(19) United States
(12) Patent Application Publication
(10) Pub. No.: US 2019/0035965 A1
(43) Pub. Date: Jan. 31, 2019

(54) GROUP III-V COMPOUND SEMICONDUCTOR SOLAR CELL, METHOD OF MANUFACTURING GROUP III-V COMPOUND SEMICONDUCTOR SOLAR CELL, AND ARTIFICIAL SATELLITE

(71) Applicant: SHARP KABUSHIKI KAISHA, Sakai City, Osaka (JP)

(72) Inventor: TAKAAKI AGUI, Sakai City (JP)

(21) Appl. No.: 16/067,502

(22) PCT Filed: Dec. 9, 2016
(86) PCT No.: PCT/JP2016/086684

§ 371 Date: Jun. 29, 2018

(30) Foreign Application Priority Data
Jan. 6, 2016 (JP) 2016-001268

(51) Int. Cl. H01L 31/0725; H01L 31/0735; H01L 31/18

(52) U.S. Cl. CPC H01L 31/0725; H01L 31/1844; H01L 31/0735

(57) ABSTRACT

A Group III-V compound semiconductor solar cell includes a buffer layer (108) and a first cell (131) both between a first electrode (121) and a second electrode (102). The buffer layer (108) has a portion in which first segments (141a, 142a, 143a, 144a) and second segments (141b, 142b, 143b, 144b) are alternately provided. Each of the first segments has a Group III element composition that continuously changes with an increasing thickness of the buffer layer (108) as traced from a side located opposite where the first cell (131) is disposed toward a side where the first cell (131) is disposed. Each of the second segments has a Group III element composition that changes without an increase in the thickness of the buffer layer (108).

### TECHNICAL FIELD

The present invention relates to Group III-V compound semiconductor solar cells, methods of manufacturing Group III-V compound semiconductor solar cells, and artificial satellites. The present application claims priority to Japanese Patent Application, Tokugan, No. 2016-001268 filed Jan. 6, 2016, the entire contents of which are incorporated herein by reference.

### BACKGROUND ART

Artificial satellites, due to their growing size, require an increasingly greater amount of electric power. Demand for high-performance solar cells is therefore has been growing. High-performance solar cells typically include those with different band gaps which are formed perpendicular to incident light. The solar cells are used as arranged in arrays.

The currently popular solar cells mounted in an artificial satellite are InGaP/InGaAs/Ge compound semiconductor solar cells formed on Ge substrates. In these compound semiconductor solar cells, the InGaP photovoltaic layer has a band gap of approximately 1.7 to 2.1 eV, the GaAs photovoltaic layer has a band gap of approximately 1.3 to 1.6 eV, and the Ge photovoltaic layer has a band gap of approximately 0.7 eV.

In triple-junction compound semiconductor solar cells, 1.93 eV/1.42 eV/1.05 eV (as traced starting from a light-receiving face) is believed to be a good combination of band gaps of photovoltaic layers for effective use of sunlight spectrum. Research is being conducted on materials with a band gap of approximately 0.9 to 1.1 eV for use as the bottom cell to provide a compound semiconductor solar cell with improved performance.

One of Group III-V compound semiconductor materials with a band gap of approximately 1 eV is InGaAs, which is used in the InGaP/GaAs/InGaAs compound semiconductor solar cell in which an InGaP cell, a GaAs cell, and an InGaAs cell are sequentially grown. These GaAs and InGaAs cells have lattice constants that differ approximately by as much as 2%.

Currently, a compromise must be made to grow an InGaAs compound semiconductor with good crystallinity on a GaAs or like semiconductor substrate that has a different lattice constant than the InGaAs compound semiconductor. Specifically, a buffer layer, which does not at all contribute to power generation, is formed between the GaAs or like semiconductor substrate and the InGaAs cell before growing the InGaAs cell (see, for example, Patent Literatures 1 to 3 and Non-patent Literatures 1 to 2).

### CITATION LIST

### Patent Literature

Patent Literature 1: Japanese Patent No. 5106880
Patent Literature 2: Japanese Unexamined Patent Application Publication, Tokukai, No. 2014-195118
Patent Literature 3: Japanese Unexamined Patent Application Publication, Tokukai, No. 2011-71548

### Non-Patent Literature

Non-patent Literature 1: J. F. Geisz et al., “Inverted GaInP/(In)GaAs/InGaAs Triple-Junction Solar Cells with Low-Stress Metamorphic Bottom Junctions”, 33th IEEE Photovoltaic Specialists Conference, 2008
Non-patent Literature 2: M. W. Wanlass et al., “Lattice-Mismatched Approaches for High-Performance, III-V Photovoltaic Energy Converters”
Non-patent Literature 3: J. W. Matthews, “Defects in Epitaxial Multilayers”, Journal of Crystal Growth 27 (1974), 118-125

### SUMMARY OF INVENTION

### Technical Problem

The multi-junction Group compound semiconductor solar cells described in Patent Literatures 1 to 3 and Non-patent Literatures 1 to 2 have serious cost-related issues because they include buffer layers that, despite making no contribution to power generation, account for as much as ¼ to ⅓ the total thickness. The step-graded buffer layer structure has an optimal step count as demonstrated by Non-patent Literature 2. It is difficult to drastically decrease the number of steps.

A critical film thickness, described in Non-patent Literature 3, needs to be taken into consideration in growing an epitaxial layer that differs from the semiconductor substrate. If the epitaxial layer has a thickness smaller than the critical film thickness, a dislocation in the epitaxial layer can propagate vertically, thereby reducing the crystallinity of the epitaxially grown film. We tried reducing the thickness of each layer in the step-graded buffer layer structure and confirmed that crystallinity dropped, which in turn resulted in drops in open-circuit voltage (V_{oc}). As can be understood from this, it is difficult to reduce the thickness of step-graded buffer layers in the conventional structure.

### Solution to Problem

An embodiment disclosed here is directed to a Group III-V compound semiconductor solar cell including: a first electrode; a second electrode; and a buffer layer and a first cell both between the first and second electrodes, wherein the buffer layer and the first cell contain a Group III-V compound semiconductor, and the buffer layer has a portion in which first segments and second segments are alternately provided, each of the first segments having a Group III element composition that continuously changes with an increasing thickness of the buffer layer as traced from a side located opposite where the first cell is disposed toward a side where the first cell is disposed, each of the second segments having a Group III element composition that changes without an increase in the thickness of the buffer layer.

Another embodiment disclosed here is directed to a method of manufacturing a Group III-V compound semiconductor solar cell, the method including: forming a buffer layer on a substrate; and forming a first cell on the buffer layer, wherein the buffer layer is formed to have a portion in which first segments and second segments are alternately provided, each of the first segments having a Group III element composition that continuously changes with an increasing thickness of the buffer layer as traced from a side located opposite where the first cell is disposed toward a side where the first cell is disposed, each of the second segments having a Group III element composition that changes without an increase in the thickness of the buffer layer.

A further embodiment disclosed here is directed to an artificial satellite including an array of any electrically connected Group III-V compound semiconductor solar cells described above.

### Advantageous Effects of Invention

The embodiments disclosed here can reduce the thickness of a buffer layer while restraining deterioration of properties.

### BRIEF DESCRIPTION OF DRAWINGS

FIG. 1 is a schematic structural cross-sectional view of a Group III-V compound semiconductor solar cell in accordance with Embodiment 1.

FIG. 2 is a schematic structural cross-sectional view of an example of a method of manufacturing a Group III-V compound semiconductor solar cell in accordance with Embodiment 1.

FIG. 3 is a schematic structural cross-sectional view of an example of a method of manufacturing a Group III-V compound semiconductor solar cell in accordance with Embodiment 1.

FIG. 4 is a schematic structural cross-sectional view of an example of a method of manufacturing a Group III-V compound semiconductor solar cell in accordance with Embodiment 1.

FIG. 5 is a schematic structural cross-sectional view of an n-type buffer layer in a Group III-V compound semiconductor solar cell in accordance with Embodiment 1.

FIG. 6 is a diagram representing a relationship between the In composition ratio and thickness of an n-type buffer layer in a Group III-V compound semiconductor solar cell in accordance with Embodiment 1.

FIG. 7 is a diagram demonstrating that the thickness of a buffer layer can be reduced in a Group III-V compound semiconductor solar cell in accordance with Embodiment 1 in comparison with the thickness of a buffer layer in a compound semiconductor solar cell of a conventional step-graded structure even if the In composition ratio is changed by a fixed amount between the start of buffer layer growth and the end of the growth.

FIG. 8 is a diagram representing a relationship between the thickness and lattice constant of an n-type buffer layer in a Group III-V compound semiconductor solar cell in accordance with Embodiment 1.

FIG. 9 is a diagram representing a relationship between the lattice constant of InₓGa_{y}P (0≤x≤1, 0≤y≤1, (x+y)>0) used to form an n-type buffer layer in a Group III-V compound semiconductor solar cell in accordance with Embodiment 1 and the mole fractions of TMI and TMG in a growth gas.

FIG. 10 is a schematic structural cross-sectional view of an example of a method of manufacturing a Group III-V compound semiconductor solar cell in accordance with Embodiment 2.

FIG. 11 is a schematic structural cross-sectional view of an example of a method of manufacturing a Group III-V compound semiconductor solar cell in accordance with Embodiment 2.

FIG. 12 is a schematic structural cross-sectional view of an example of a method of manufacturing a Group III-V compound semiconductor solar cell in accordance with Embodiment 2.

FIG. 13 is a schematic structural cross-sectional view of a Group III-V compound semiconductor solar cell in accordance with Embodiment 3.

FIG. 14 is a schematic structural cross-sectional view of an example of a method of manufacturing a Group III-V compound semiconductor solar cell in accordance with Embodiment 3.

FIG. 15 is a schematic structural cross-sectional view of an example of a method of manufacturing a Group III-V compound semiconductor solar cell in accordance with Embodiment 3.

FIG. 16 is a schematic structural cross-sectional view of an example of a method of manufacturing a Group III-V compound semiconductor solar cell in accordance with Embodiment 3.

FIG. 17 is a schematic structural cross-sectional view of a Group III-V compound semiconductor solar cell in accordance with Embodiment 4.

FIG. 18 is a schematic structural cross-sectional view of a Group III-V compound semiconductor solar cell in accordance with Embodiment 5.

FIG. 19 is a schematic structural cross-sectional view of a Group III-V compound semiconductor solar cell in accordance with Embodiment 6.

FIG. 20(a) is a schematic perspective view of an artificial satellite in accordance with Embodiment 7; FIG. 20(b) is a schematic plan view of a solar cell array in accordance with Embodiment 7 used in the artificial satellite in accordance with Embodiment 7; and FIG. 20(c) is a schematic plan view of Group III-V compound semiconductor solar cells in accordance with Embodiments 1 to 6 used in the solar cell array in accordance with Embodiment 7.

FIGS. 21(a) to 21(d) are diagrams representing a relationship between the thickness and V_{oc} of a buffer layer in a Group III-V compound semiconductor solar cell in accordance with Reference Examples 1 to 4; and FIG. 21(e) is a diagram representing a relationship between the thickness and V_{oc} of a buffer layer in a Group III-V compound semiconductor solar cell in accordance with a working example.

### DESCRIPTION OF EMBODIMENTS

The following will describe embodiments. The same reference numerals in the drawings referred to in the description of embodiments denote identical or equivalent members.

### Embodiment 1

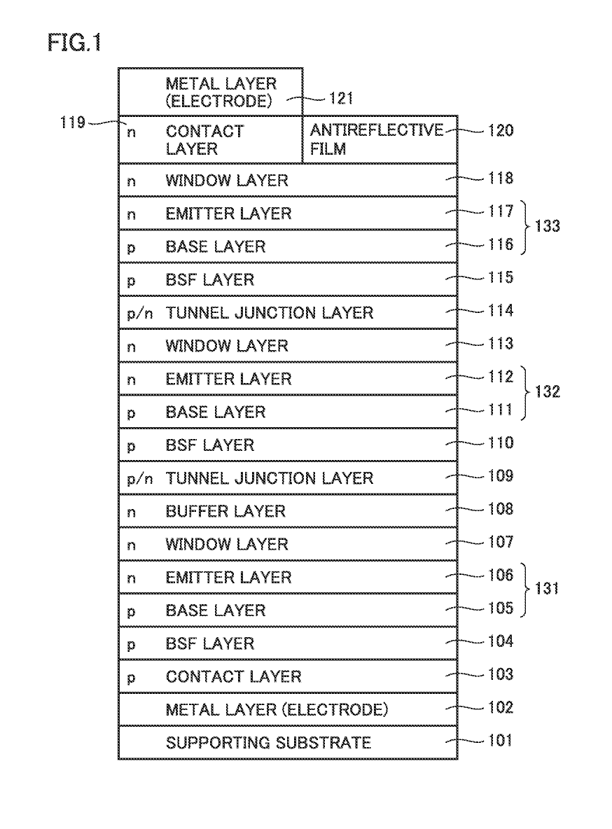

FIG. 1 is a schematic structural cross-sectional view of a Group III-V compound semiconductor solar cell in accordance with Embodiment 1. As shown in FIG. 1, a Group III-V compound semiconductor solar cell in accordance with Embodiment 1 has a structure in which a metal layer 102 (electrode), a p-type contact layer 103, a p-type BSF layer 104, a p-type base layer 105, an n-type emitter layer 106, and an n-type window layer 107 are stacked in this sequence on a supporting substrate 101. The p-type BSF layer 104 and the p-type base layer 105, the latter being composed of p-type InGaAs, have equal or similar lattice constants.

An n-type buffer layer 108 is stacked on the n-type window layer 107. In the present embodiment, the n-type buffer layer 108 has the following structure. An E sublayer (e.g., 0.5 μm thick) composed of n-type In_{0.82}Ga_{0.18}P is stacked on the n-type InGaP window layer 107. An A sublayer (e.g., 0.3 μm thick) is stacked on the E sublayer. The A sublayer has an In composition ratio that continuously changes (in the present embodiment, linearly decreases (monotonically decreases)) from n-type In_{0.78}Ga_{0.22}P to n-type In_{0.73}Ga_{0.27}P. A B sublayer (e.g., 0.3 μm thick) is stacked on the A sublayer. The B sublayer has an In composition ratio that continuously changes (monotonically decreases) from n-type In_{0.69}Ga_{0.31}P to n-type In_{0.65}Ga_{0.35}P. A C sublayer (e.g., 0.3 μm thick) is stacked on the B sublayer. The C sublayer has an In composition ratio that continuously changes (monotonically decreases) from n-type In_{0.61}Ga_{0.39}P to n-type In_{0.56}Ga_{0.44}P. A D sublayer (e.g., 0.3 μm thick) is stacked on the C sublayer. The D sublayer has an In composition ratio that continuously changes (monotonically decreases) from n-type In_{0.52}Ga_{0.48}P to n-type In_{0.48}Ga_{0.52}P.

On the n-type buffer layer 108 are there stacked an n-type layer and a p-type layer in this sequence so as to form a tunnel junction layer 109.

On the tunnel junction layer 109 are there stacked a p-type BSF layer 110, a p-type base layer 111, an n-type emitter layer 112, and an n-type window layer 113 in this sequence. The p-type BSF layer 110 and the p-type base layer 111, the latter being composed of p-type GaAs, have equal or similar lattice constants. The n- and p-type layers that make up the tunnel junction layer 109 also have lattice constants that are equal or similar to that of the p-type base layer 111.

On the n-type window layer 113 are there stacked an n-type layer and a p-type layer in this sequence so as to form a tunnel junction layer 114.

On the tunnel junction layer 114 are there stacked a p-type BSF layer 115, a p-type base layer 116, an n-type emitter layer 117, and an n-type window layer 118 in this sequence. The p-type BSF layer 115 and the p-type base layer 116, the latter being composed of p-type InGaP, have equal or similar lattice constants.

An n-type contact layer 119 and an antireflective film 120 are provided on the n-type window layer 118, and a metal layer 121 (electrode) is provided on the n-type contact layer 119.

In the Group III-V compound semiconductor solar cell in accordance with Embodiment 1, the band gap increases in the order of the compound semiconductor layers that make up a bottom cell 131, the compound semiconductor layers that make up a middle cell 132, and the compound semiconductor layers that make up a top cell 133.

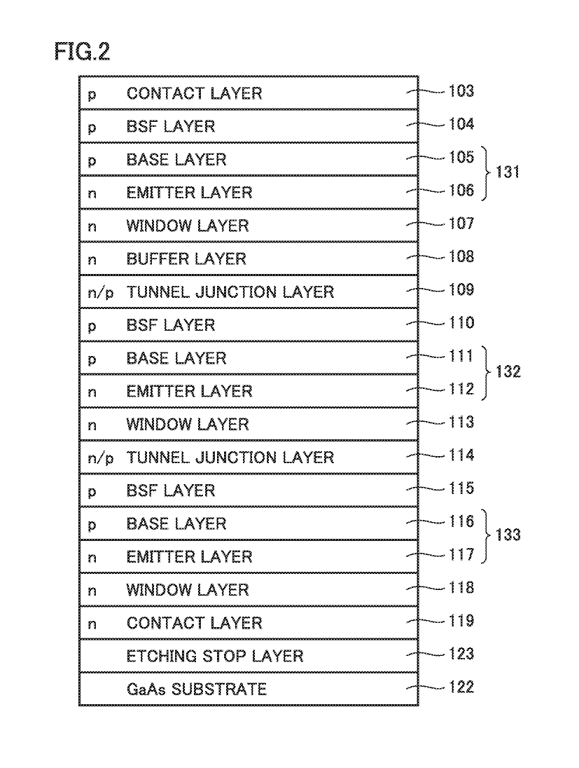

The following will describe an example of a method of manufacturing a Group III-V compound semiconductor solar cell in accordance with Embodiment 1 in reference to the schematic structural cross-sectional views in FIGS. 2 to 4.

First, as shown in FIG. 2, a GaAs substrate 122 is placed in a metal-organic chemical vapor deposition (“MOCVD”) device. An etching stop layer 123, the n-type contact layer 119, the n-type window layer 118, the n-type emitter layer 117, the p-type base layer 116, and the p-type BSF layer 115 are then epitaxially grown in this sequence on the GaAs substrate 122 by MOCVD. The etching stop layer 123 and GaAs can be etched selectively.

Next, the tunnel junction layer 114 is formed on the p-type BSF layer 115 by MOCVD.

Then, the n-type window layer 113, the n-type emitter layer 112, the p-type base layer 111, and the p-type BSF layer 110 are epitaxially grown in this sequence on the tunnel junction layer 114 by MOCVD.

Next, the tunnel junction layer 109 is formed on the p-type BSF layer 110 by MOCVD.

Next, the n-type buffer layer 108 is epitaxially grown on the tunnel junction layer 109 by MOCVD. In the present embodiment, the n-type buffer layer 108 is epitaxially grown in the following manner. First, the flow rates of TMI (trimethyl indium) and TMG (trimethyl gallium), which are Group III element gases, are adjusted so as to grow n-type In_{0.48}Ga_{0.52}P. After the flow rates are adjusted, this mixed growth gas starts to be introduced into a chamber. Throughout the introduction of the growth gas into the chamber, the ratio of the flow rate of TMI to the total flow rate of TMI and TMG in the growth gas is continuously increased (in the present embodiment, linearly increased (monotonically increased)). These procedures grow the D sublayer in which the In composition ratio continuously changes (monotonically increases) from n-type In_{0.48}Ga_{0.52}P to n-type In_{0.52}Ga_{0.48}P.

Next, the growth gas stops being introduced into the chamber. Then, with no growth gas being introduced into the chamber, the flow rates are adjusted so as to further increase the ratio of the flow rate of TMI to the total flow rate of TMI and TMG.

After the flow rates are adjusted, this growth gas starts to be introduced into the chamber. Throughout the introduction of the growth gas into the chamber, the ratio of the flow rate of TMI to the total flow rate of TMI and TMG in the growth gas is continuously increased (monotonically increased). These procedures grow, on the D sublayer, the C sublayer in which the In composition ratio continuously changes (monotonically increases) from n-type In_{0.56}Ga_{0.44}P to n-type In_{0.61}Ga_{0.39}P.

Next, the growth gas stops being introduced into the chamber. Then, with no growth gas being introduced into the chamber, the flow rates are adjusted so as to further increase the ratio of the flow rate of TMI to the total flow rate of TMI and TMG.

After the flow rates are adjusted, this growth gas starts to be introduced into the chamber. Throughout the introduction of the growth gas into the chamber, the ratio of the flow rate of TMI to the total flow rate of TMI and TMG in the growth gas is continuously increased (monotonically increased). These procedures grow, on the C sublayer, the B sublayer in which the In composition ratio continuously changes (monotonically increases) from n-type In_{0.65}Ga_{0.35}P to n-type In_{0.69}Ga_{0.31}P.

Next, the growth gas stops being introduced into the chamber. Then, with no growth gas being introduced into the chamber, the flow rates are adjusted so as to further increase the ratio of the flow rate of TMI to the total flow rate of TMI and TMG.

After the flow rates are adjusted, this growth gas starts to be introduced into the chamber. Throughout the introduction of the growth gas into the chamber, the ratio of the flow rate of TMI to the total flow rate of TMI and TMG in the growth gas is continuously increased (monotonically increased). These procedures grow, on the B sublayer, the A sublayer in which the In composition ratio continuously changes (monotonically increases) from n-type In_{0.73}Ga_{0.27}P to n-type In_{0.78}Ga_{0.22}P.

Next, the growth gas stops being introduced into the chamber. Then, with no growth gas being introduced into the chamber, the flow rates are adjusted so as to further increase the ratio of the flow rate of TMI to the total flow rate of TMI and TMG.

After the flow rates are adjusted, this growth gas starts to be introduced into the chamber. The growth gas is introduced into the chamber, this time without changing the ratio of the flow rate of TMI to the total flow rate of TMI and TMG in the growth gas. These procedures grow, on the A sublayer, the E sublayer composed of n-type In_{0.82}Ga_{0.18}P, which completes the epitaxial growth of the n-type buffer layer 108 on the tunnel junction layer 109.

Next, the n-type window layer 107, the n-type emitter layer 106, the p-type base layer 105, the p-type BSF layer 104, and the p-type contact layer 103 are epitaxially grown in this sequence by MOCVD on the n-type In_{0.82}Ga_{0.18}P E sublayer which is a part of the n-type buffer layer 108.

In the present embodiment, the growth gas may be, for example, a combination of AsH₃ (arsine) and TMG for the provision of GaAs, a combination of TMI, TMG, and PH₃ (phosphine) for the provision of InGaP, a combination of TMI, TMG, and AsH₃ for the provision of InGaAs, a combination of TMA (trimethyl aluminum), TMI, and PH₃ for the provision of AlInP, a combination of TMA, TMG, and AsH₃ for the provision of AlGaAs, and a combination of TMA, TMI, TMG, and AsH₃ for the provision of AlInGaAs. The growth gas may contain other gases including n- and p-type dopant gases.

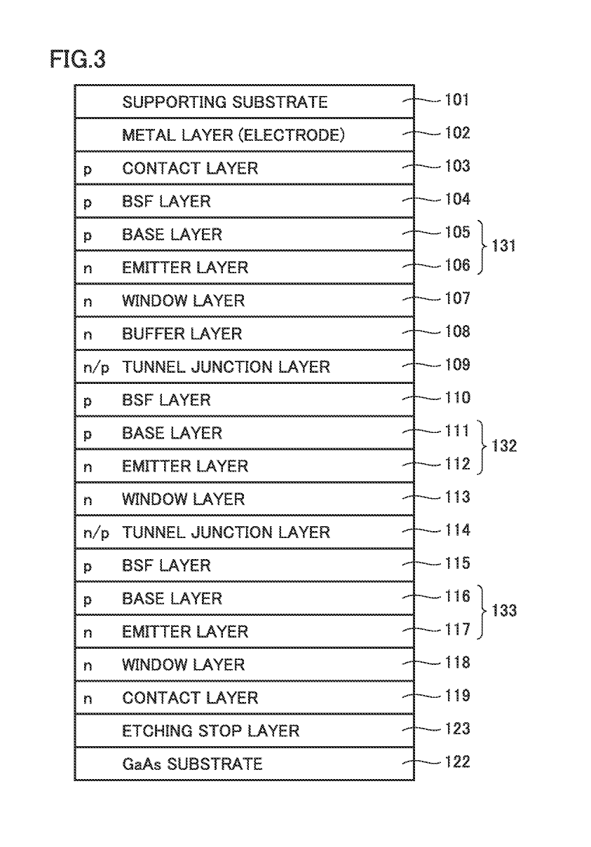

Next, as shown in FIG. 3, the metal layer 102 is formed on the p-type contact layer 103, and the supporting substrate 101 is attached onto the metal layer 102. The metal layer 102 is composed of, for example, a Au—Ag laminate.

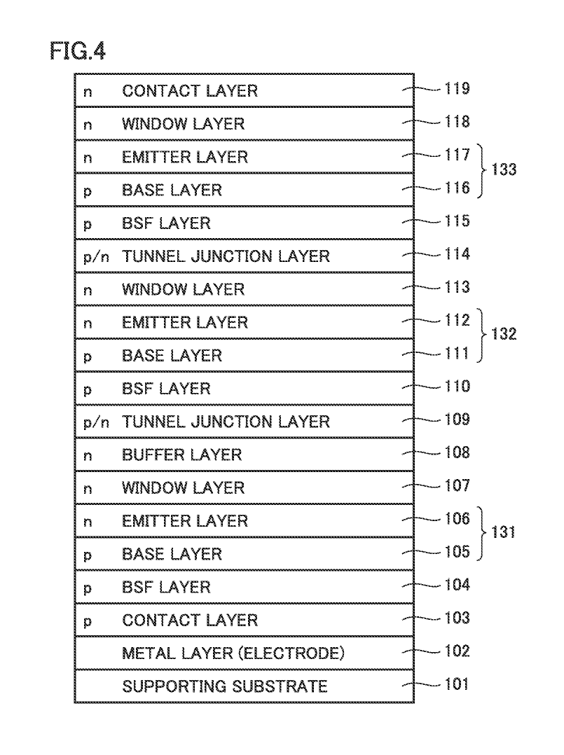

Next, as shown in FIG. 4, after etching the GaAs substrate 122 with an alkali aqueous solution, the etching stop layer 123 is etched with an acid aqueous solution.

Next, a resist pattern is formed on the n-type GaAs contact layer 119 by photolithography. After the resist pattern is formed, the contact layer 119 is partially removed by etching using an alkali aqueous solution. A resist pattern is then formed on the surface of the remaining contact layer 119 again by photolithography. Subsequently, the metal layer 121, composed of, for example, an AuGe—Ni—Au—Ag laminate, is formed using a resistance heating vapor deposition device and an electron beam (EB) vapor deposition device.

Next, a mesa etching pattern is formed. After that, mesa etching is performed using an alkali aqueous solution and an acid solution. A laminate of, for example, a TiO₂ film and an Al₂O₃ film is then formed by electron beam (EB) vapor deposition, to provide the antireflective film 120. That concludes the manufacture of a Group III-V compound semiconductor solar cell in accordance with Embodiment 1 that has the structure shown in FIG. 1 in which the compound semiconductor solar cell has a light-receiving face on a side located opposite the direction of growth of the compound semiconductors.

FIG. 5 is a schematic structural cross-sectional view of the n-type buffer layer 108 in the Group III-V compound semiconductor solar cell in accordance with Embodiment 1. As shown in FIG. 5, the n-type buffer layer 108 has a structure in which a D sublayer 141a, a C sublayer 142a, a B sublayer 143a, an A sublayer 144a, and an E sublayer 145a are stacked sequentially from a side located opposite where the bottom cell 131 is disposed toward the side where the bottom cell 131 is disposed. In each of the D sublayer 141a, the C sublayer 142a, the B sublayer 143a, and the A sublayer 144a of the n-type buffer layer 108, the composition ratio of In, a Group III element, continuously increases with an increasing thickness of the n-type buffer layer 108 (as traced from a side located opposite where the bottom cell 131 is disposed toward the side where the bottom cell 131 is disposed).

The In composition ratio jumps from 0.52 to 0.56 across an A interface 141b, which makes an interface between the D sublayer 141a and the C sublayer 142a, without an increase in the thickness of the n-type buffer layer 108.

The In composition ratio jumps from 0.61 to 0.65 across a B interface 142b, which makes an interface between the C sublayer 142a and the B sublayer 143a, without an increase in the thickness of the n-type buffer layer 108.

The In composition ratio jumps from 0.69 to 0.73 across a C interface 143b, which makes an interface between the B sublayer 143a and the A sublayer 144a, without an increase in the thickness of the n-type buffer layer 108.

The In composition ratio jumps from 0.78 to 0.82 across a D interface 144b, which makes an interface between the A sublayer 144a and the E sublayer 145a, without an increase in the thickness of the n-type buffer layer 108.

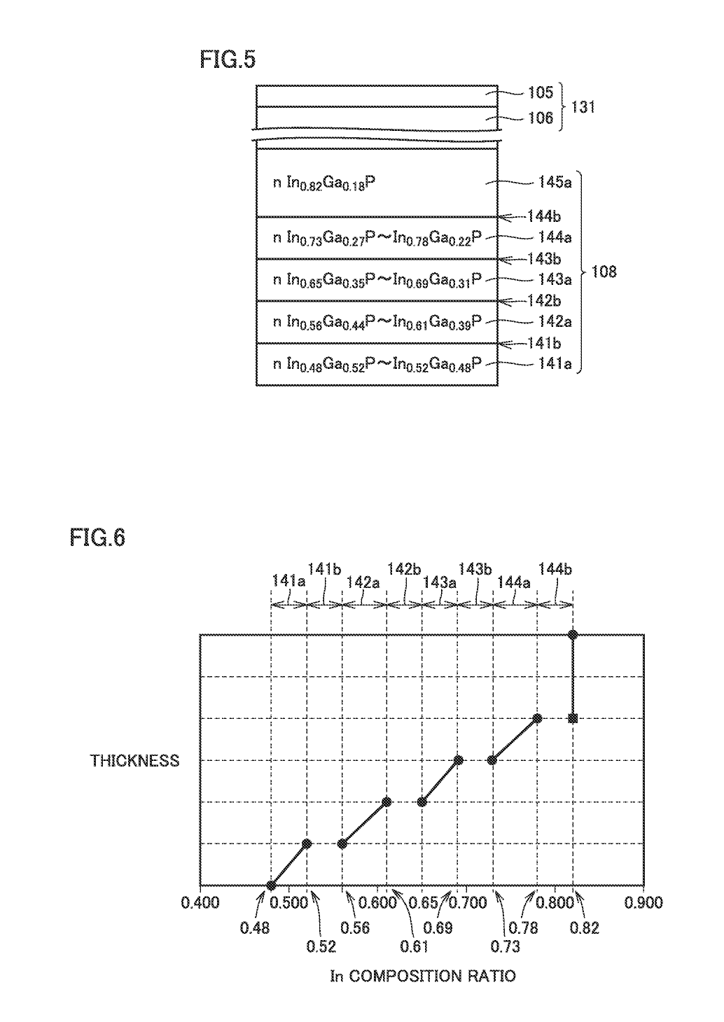

FIG. 6 represents a relationship between the In composition ratio and thickness of the n-type buffer layer 108 in the Group III-V compound semiconductor solar cell in accordance with Embodiment 1. As shown in FIG. 6, the n-type buffer layer 108 of the Group III-V compound semiconductor solar cell in accordance with Embodiment 1 has a portion in which first segments and second segments are alternately provided. The “first segments” refer to the D sublayer 141a, the C sublayer 142a, the B sublayer 143a, and the A sublayer 144a in each of which the In composition ratio monotonically increases with an increasing thickness of the n-type buffer layer 108 as traced from a side located opposite where the bottom cell 131 is disposed toward the side where the bottom cell 131 is disposed. The “second segments” refer to the A interface 141b, the B interface 142b, the C interface 143b, and the D interface 144b across each of which the In composition ratio monotonically increases without an increase in the thickness of the n-type buffer layer 108.

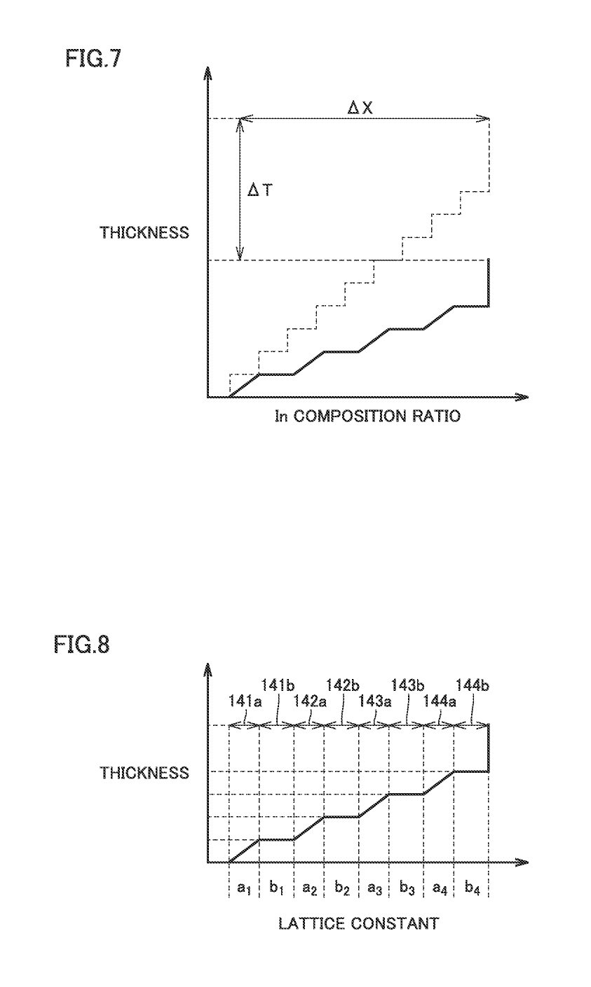

Therefore, in the Group III-V compound semiconductor solar cell in accordance with Embodiment 1, even if the In composition ratio is changed by a fixed total amount (denoted by Δx in FIG. 7) between the start of buffer layer growth and the end of the growth as shown in FIG. 7 as an example, the thickness of the n-type buffer layer 108 can be reduced (as denoted by ΔT) in comparison with the thickness of a buffer layer in a compound semiconductor solar cell of a conventional step-graded structure.

It may be possible, in the conventional step-graded buffer layer structure, to restrain increases of the thickness of the buffer layer while preserving a fixed total amount (Δx) of change of the In composition ratio to be achieved between the start of buffer layer growth and the end of the growth, by increasing the amount of change of the In composition ratio across each interface between sublayers in the buffer layer. In such a case, however, the amount of change of the In composition ratio across each interface between sublayers in the buffer layer may become excessively large, which will increase crystal defects in the sublayers of the buffer layer and may result in crystal defects propagating into crystals in the cell grown on the buffer layer. Conventional cells could hence exhibit poorer properties than the Group III-V compound semiconductor solar cell in accordance with Embodiment 1.

Propagation of crystal defects can be stopped by interfaces between sublayers in the n-type buffer layer 108. This structure can reduce crystal defects that propagate into crystals in the bottom cell 131 grown on the n-type buffer layer 108.

For these reasons, the Group III-V compound semiconductor solar cell in accordance with Embodiment 1 allows for reduction of the thickness of the buffer layer while restraining deterioration of properties.

In the E sublayer, which is located closest to the bottom cell 131 of all the sublayers making up the n-type buffer layer 108, the amount of change of the In composition ratio is zero. This is the smallest of the amounts of change of the In composition ratio that occur in the sublayers of the n-type buffer layer 108. This structure can more efficiently reduce crystal defects that propagate from the n-type buffer layer 108 to the bottom cell 131.

The amount of change of the In composition ratio in each sublayer (i.e., in each first segment) is preferably less than or equal to 0.08. Under such conditions, the In composition ratio does not undergo excessively abrupt changes in the sublayers. That can in turn reduce crystal defects that occur during the growth of the sublayers of the n-type buffer layer 108.

The amount of change of the In composition ratio in each sublayer (i.e., the amount of change of a Group III element composition in each first segment) is equal to the absolute value of the value obtained by subtracting the In composition ratio on a face of the sublayer located opposite from where the bottom cell 131 is disposed from the In composition ratio on a face of the sublayer facing where the bottom cell 131 is disposed. In the present embodiment, the amount of change of the In composition ratio in the A sublayer 144a is 0.78-0.73=0.04, the amount of change of the In composition ratio in the B sublayer 143a is 0.69-0.65=0.05, the amount of change of the In composition ratio in the C sublayer 142a is 0.61-0.56=0.04, and the amount of change of the In composition ratio in the D sublayer 141a is 0.52-0.48=0.04.

The total sum of the amounts of change of the In composition ratio in the sublayers (i.e., in the first segments in the n-type buffer layer 108) is preferably more than or equal to ⅓ the total sum of the amounts of change of the In composition ratio across the interfaces (i.e., across the second segments in the n-type buffer layer 108). Under such conditions, the thickness of the n-type buffer layer 108 may be further reduced.

The total sum of the amounts of change of the In composition ratio in the A sublayer 144a, the B sublayer 143a, the C sublayer 142a, and the D sublayer 141a is 0.04+0.05+0.04+0.04=0.17.

The amount of change of the In composition ratio across each interface (i.e., the amount of change of a Group III element composition across each second segment) is equal to the absolute value of the value obtained by subtracting the In composition ratio on a face of one of the two sublayers bordering at that interface, that one of the sublayers being located opposite from where the bottom cell 131 is disposed, the face facing where the bottom cell 131 is disposed, from the In composition ratio on a face of the other sublayer facing where the bottom cell 131 is disposed, the face located opposite from where the bottom cell 131 is disposed.

The amount of change of the In composition ratio across the A interface 141b is 0.56−0.52=0.04, the amount of change of the In composition ratio across the B interface 142b is 0.65-0.61=0.04, the amount of change of the In composition ratio across the C interface 143b is 0.73-0.69=0.04, and the amount of change of the In composition ratio across the D interface 144b is 0.82-0.78=0.04. Therefore, the total sum of the amounts of change of the In composition ratio across the A interface 141b, the B interface 142b, the C interface 143b, and the D interface 144b is 0.04+0.04+0.04+0.04=0.16.

Thus, the total sum of the amounts of change of the In composition ratio in the sublayers (i.e., in the first segments in the n-type buffer layer 108) (=0.17) is approximately 1.06 times the total sum of the amounts of change of the In composition ratio across the interfaces (i.e., across the second segments in the n-type buffer layer 108) (=0.16). This structure can further reduce the thickness of the n-type buffer layer 108.

In a Group III-V compound semiconductor, the Group III element composition maps one by one to the lattice constant of the Group III-V compound. Therefore, the lattice constant of a Group III-V compound changes with a change in the Group III element composition. FIG. 8 represents a relationship between the thickness and lattice constant of the n-type buffer layer 108 in the Group III-V compound semiconductor solar cell in accordance with Embodiment 1. In FIG. 8, the amount of change of the lattice constant in the A sublayer 144a is denoted by a1, the amount of change of the lattice constant in the B sublayer 143a is denoted by a2, the amount of change of the lattice constant in the C sublayer 142a is denoted by a3, and the amount of change of the lattice constant in the D sublayer 141a is denoted by a4. Also in FIG. 8, the amount of change of the lattice constant across the A interface 141b is denoted by b1, the amount of change of the lattice constant across the B interface 142b is denoted by b2, the amount of change of the lattice constant across the C interface 143b is denoted by b3, and the amount of change of the lattice constant across the D interface 144b is denoted by b4.

As shown in FIG. 8, the lattice constant continuously increases (monotonically increases) with an increasing thickness of the n-type buffer layer 108 through the A sublayer 144a, the B sublayer 143a, the C sublayer 142a, and the D sublayer 141a (i.e., through the first segments). Meanwhile, the lattice constant increases across the A interface 141b, the B interface 142b, the C interface 143b, and the D interface 144b (i.e., across the second segments) without an increase in the thickness of the n-type buffer layer 108.

In the E sublayer, which is located closest to the bottom cell 131 of all the sublayers making up the n-type buffer layer 108, the amount of change of the lattice constant is zero. This is the smallest of the amounts of change of the lattice constant that occur in the sublayers of the n-type buffer layer 108. This structure can more efficiently reduce crystal defects that propagate from the n-type buffer layer 108 to the bottom cell 131.

The rate of change of the lattice constant in each first segment is preferably from 0.1% to 1% inclusive and more preferably from 0.2% to 0.4% inclusive. Under such conditions, the rate of change of the lattice constant in the sublayers is not too steep. That can in turn reduce crystal defects that occur during the growth of the sublayers of the n-type buffer layer 108.

The rate of change of the lattice constant in each sublayer (i.e., in each first segment) is equal to the percentage of the value obtained by subtracting the lattice constant on a face of that sublayer located opposite from where the bottom cell 131 is disposed from the lattice constant on the other face of the sublayer facing where the bottom cell 131 is disposed to the lattice constant on the face of the sublayer located opposite from where the bottom cell 131 is disposed.

The total sum of the amounts of change of the lattice constant in the sublayers (i.e., in the first segments in the n-type buffer layer 108) is preferably more than or equal to ⅓ the total sum of the amounts of change of the lattice constant across the interfaces (i.e., across the second segments in the n-type buffer layer 108). Under such conditions, the thickness of the n-type buffer layer 108 may be further reduced. In the example shown in FIG. 8, since the total sum of the amounts of change of the lattice constant in the sublayers is equal to a1+a2+a3+a4, and the total sum of the amounts of change of the lattice constant across the interfaces is equal to b1+b2+b3+b4, it is preferable that the following relational inequality be met: (a1+a2+a3+a4)≥⅓ (b1+b2+b3+b4).

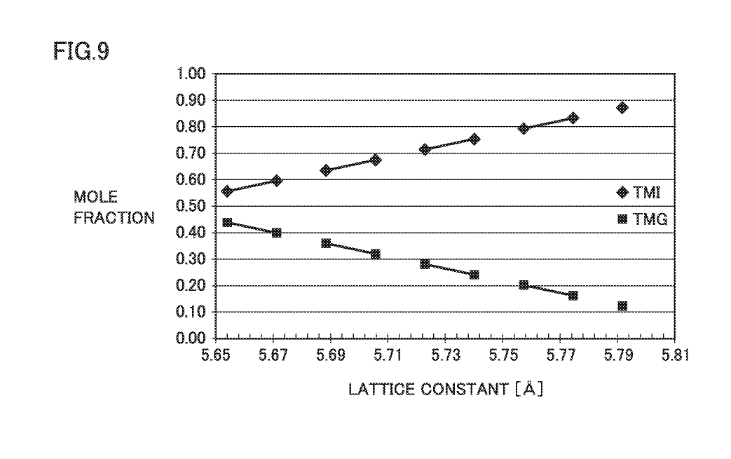

FIG. 9 represents a relationship between the lattice constant of InₓGa_{y}P (0≤x≤1, 0≤y≤1, (x+y)>0) used to form the n-type buffer layer 108 and the mole fractions of TMI and TMG in a growth gas. It is understood from FIG. 9 that the lattice constant increases with an increase in the mole fraction of TMI in the growth gas.

In the foregoing description, indium has been taken as an example of a composition-varying Group III element. A Group III element(s) (e.g., Al and/or Ga) other than indium may be used as a composition-varying Group III element(s). The Group III element composition can be determined by secondary ion mass spectrometry (“SIMS”). The lattice constant can be derived from the Group III element composition determined by SIMS.

In this specification, a compound may be described in the form of a chemical formula that does not specify the composition ratios of the elements making up the compound. The composition ratio of such an element with no given composition ratio is not limited in any particular manner and may be of any suitable value.

A compound may be described in the form of a chemical formula that specifies the composition ratios of the elements making up the compound in this specification. Still, the present invention is by no means limited by these composition ratios.

### Embodiment 2

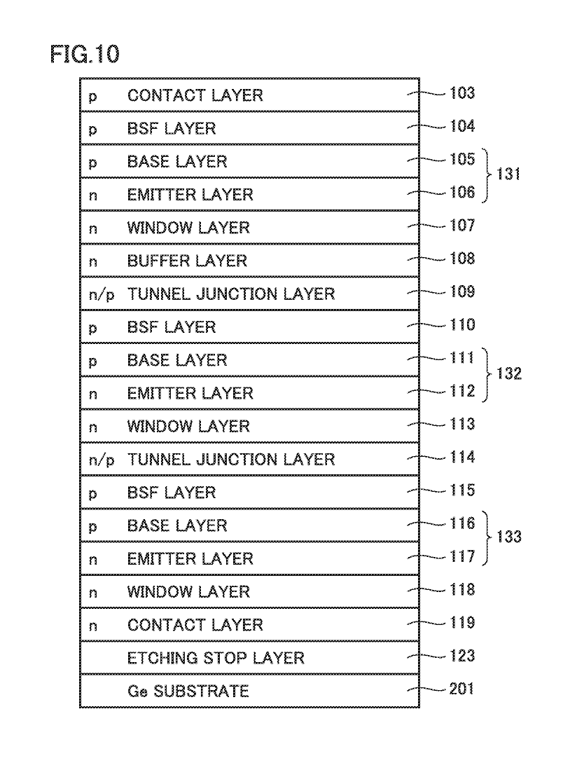

FIGS. 10 to 12 are schematic structural cross-sectional views illustrating an example of a method of manufacturing a Group III-V compound semiconductor solar cell in accordance with Embodiment 2. The Group III-V compound semiconductor solar cell in accordance with Embodiment 2 has features that it is formed by growing compound semiconductor layers on a Ge substrate 201 and that the top, middle, and bottom cells each have a lattice constant matched with the lattice constant of Ge. Otherwise, the Group III-V compound semiconductor solar cell in accordance with Embodiment 2 has the same structure as the Group III-V compound semiconductor solar cell in accordance with Embodiment 1.

First, as shown in FIG. 10, an etching stop layer 123, an n-type contact layer 119, an n-type window layer 118, an n-type emitter layer 117, a p-type base layer 116, and a p-type BSF layer 115 are stacked in this sequence on the Ge substrate 201 by MOCVD. The etching stop layer 123 has substantially the same lattice constant as Ge. The n-type window layer 118 and the base layer 116, the latter being composed of p-type InGaP, have equal or similar lattice constants.

A tunnel junction layer 114 is stacked on the p-type BSF layer 115 by MOCVD. Thereafter, an n-type window layer 113, an n-type emitter layer 112, a p-type base layer 111, and a p-type BSF layer 110 are stacked in this sequence on the tunnel junction layer 114 by MOCVD. The n-type window layer 113 and the p-type base layer 111, the latter being composed of p-type InGaAs, have equal or similar lattice constants. Under these conditions, the p-type base layer 111 and the Ge substrate 201 have substantially the same lattice constants.

A tunnel junction layer 109 is then stacked on the p-type BSF layer 110 by MOCVD. Thereafter, an n-type window layer 107, an n-type emitter layer 106, a p-type base layer 105, and a p-type BSF layer 104 are stacked in this sequence on the tunnel junction layer 109 by MOCVD. The n-type window layer 107 and the p-type base layer 105, the latter being composed of p-type InGaAs, have equal or similar lattice constants. A p-type contact layer 103 is then stacked on the p-type BSF layer 104 by MOCVD.

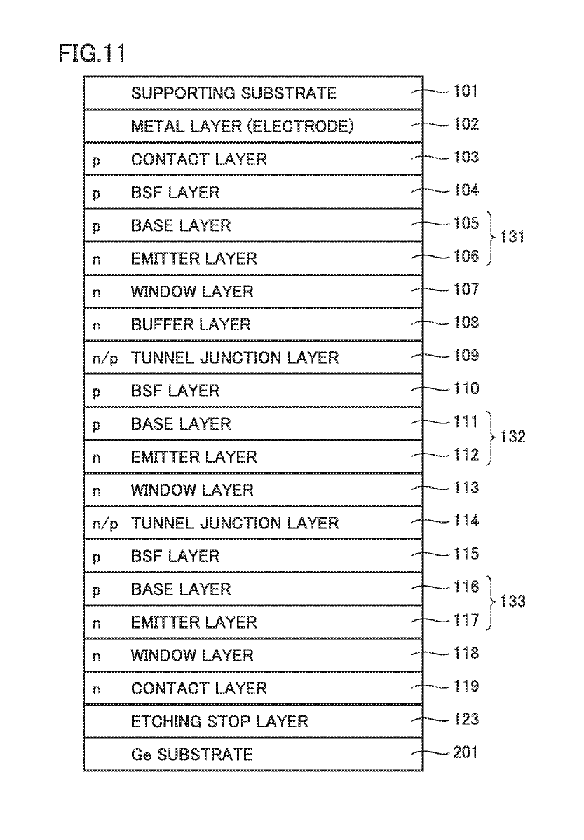

Next, as shown in FIG. 11, a supporting substrate 101 is attached onto the p-type contact layer 103 via a metal layer 102.

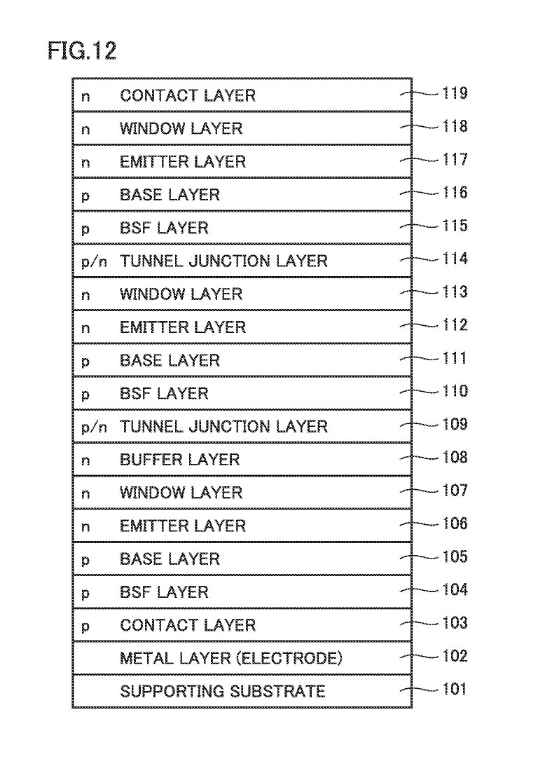

Next, as shown in FIG. 12, after etching the Ge substrate 201 with an alkali aqueous solution, the etching stop layer 123 is etched with an acid aqueous solution.

Next, the contact layer 119, composed of n-type GaAs, is partially removed, and a metal layer 121 and an antireflective film 120 are formed.

In other respects, the same description as given in Embodiment 1 applies to Embodiment 2. The description is therefore not repeated here.

### Embodiment 3

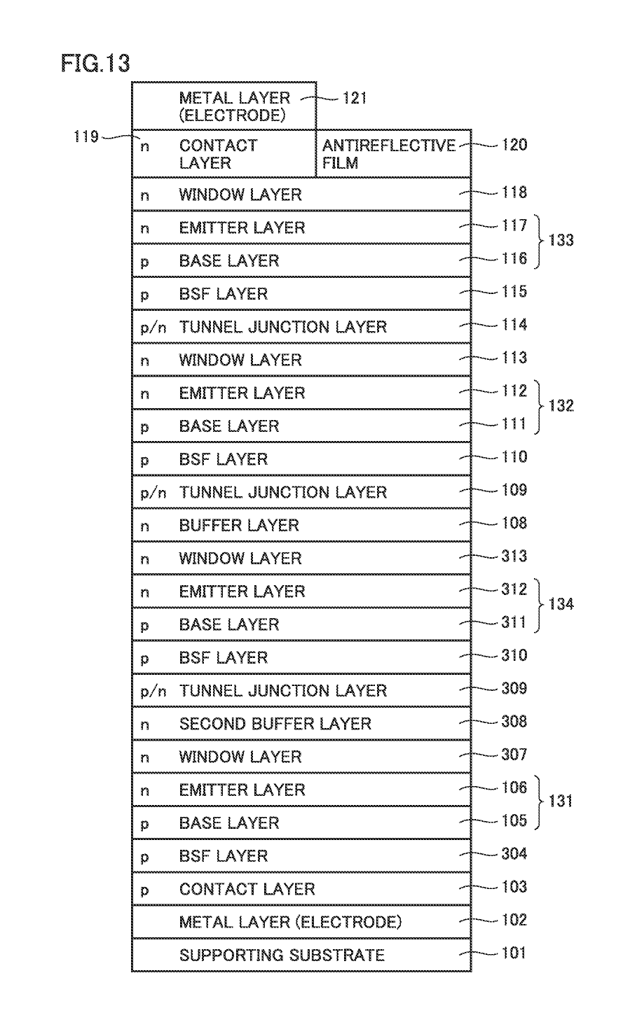

FIG. 13 is a schematic structural cross-sectional view of a Group III-V compound semiconductor solar cell in accordance with Embodiment 3. The Group III-V compound semiconductor solar cell in accordance with Embodiment 3 has a feature that it is a quadruple-junction Group III-V compound semiconductor solar cell.

As shown in FIG. 13, the Group III-V compound semiconductor solar cell in accordance with Embodiment 3 has a structure in which a metal layer 102 (electrode), a p-type contact layer 103, a p-type BSF layer 304, a p-type base layer 105, an n-type emitter layer 106, and an n-type window layer 307 are stacked in this sequence on a supporting substrate 101. The p-type BSF layer 304 and the p-type base layer 105, the latter being composed of p-type InGaAs, have equal or similar lattice constants.

A second n-type buffer layer 308 is stacked on the n-type window layer 307. In the present embodiment, the second n-type buffer layer 308 has the following structure. An F sublayer (e.g., 0.5 μm thick) composed of n-type (Al_{0.6}Ga_{0.4})_{0.38}In_{0.62}As is stacked on the n-type window layer 307. A G sublayer (e.g., 0.3 μm thick) is stacked on the F sublayer. The G sublayer has an In composition ratio that continuously changes (in the present embodiment, linearly decreases (monotonically decreases)) from n-type (Al_{0.6}Ga_{0.4})_{0.43}In_{0.57}As to n-type (Al_{0.6}Ga_{0.4})_{0.48}In_{0.52}As. An H sublayer (e.g., 0.3 μm thick) is stacked on the G sublayer. The H sublayer has an In composition ratio that continuously changes (monotonically decreases) from n-type (Al_{0.6}Ga_{0.4})_{0.54}In_{0.46}As to n-type (Al_{0.6}Ga_{0.4})_{0.59}In_{0.41}As. An I sublayer (e.g., 0.3 μm thick) is stacked on the H sublayer. The I sublayer has an In composition ratio that continuously changes (monotonically decreases) from n-type (Al_{0.6}Ga_{0.4})_{0.64}In_{0.36}As to n-type (Al_{0.6}Ga_{0.4})_{0.69}In_{0.31}As.

On the second n-type buffer layer 308 are there stacked an n-type layer and a p-type layer in this sequence so as to form a tunnel junction layer 309.

On the tunnel junction layer 309 are there stacked a p-type BSF layer 310, a p-type base layer 311, an n-type emitter layer 312, and an n-type window layer 313 in this sequence. The p-type BSF layer 310 and the p-type base layer 311, the latter being composed of p-type InGaAs, have equal or similar lattice constants. The p-type base layer 311 and the n-type emitter layer 312 combine to form a first middle cell 134. The n- and p-type layers that make up the tunnel junction layer 309 also have lattice constants that are equal or similar to that of the p-type base layer 311.

An n-type buffer layer 108 is stacked on the n-type window layer 313. This n-type buffer layer 108 has the same configuration as the n-type buffer layer 108 of Embodiment 1.

A tunnel junction layer 109 is stacked on the n-type buffer layer 108.

On the tunnel junction layer 109 are there stacked a p-type BSF layer 110, a p-type base layer 111, an n-type emitter layer 112, and an n-type window layer 113 in this sequence. The p-type BSF layer 110 and the p-type base layer 111, the latter being composed of p-type GaAs, have equal or similar lattice constants. The p-type base layer 111 and the n-type emitter layer 112 combine to form a second middle cell 132.

A tunnel junction layer 114 is stacked on the n-type window layer 113.

On the tunnel junction layer 114 are there stacked a p-type BSF layer 115, a p-type base layer 116, an n-type emitter layer 117, and an n-type window layer 118 in this sequence. The p-type BSF layer 115 and the p-type base layer 116, the latter being composed of p-type InGaP, have equal or similar lattice constants.

An n-type contact layer 119 and the antireflective film 120 are provided on the n-type window layer 118. A metal layer 121 (electrode) is provided on the contact layer 119.

In the Group III-V compound semiconductor solar cell in accordance with Embodiment 1, the band gap increases in the order of the compound semiconductor layers that make up a bottom cell 131, the compound semiconductor layers that make up the first middle cell 134, the compound semiconductor layers that make up the second middle cell 132, and the compound semiconductor layers that make up a top cell 133.

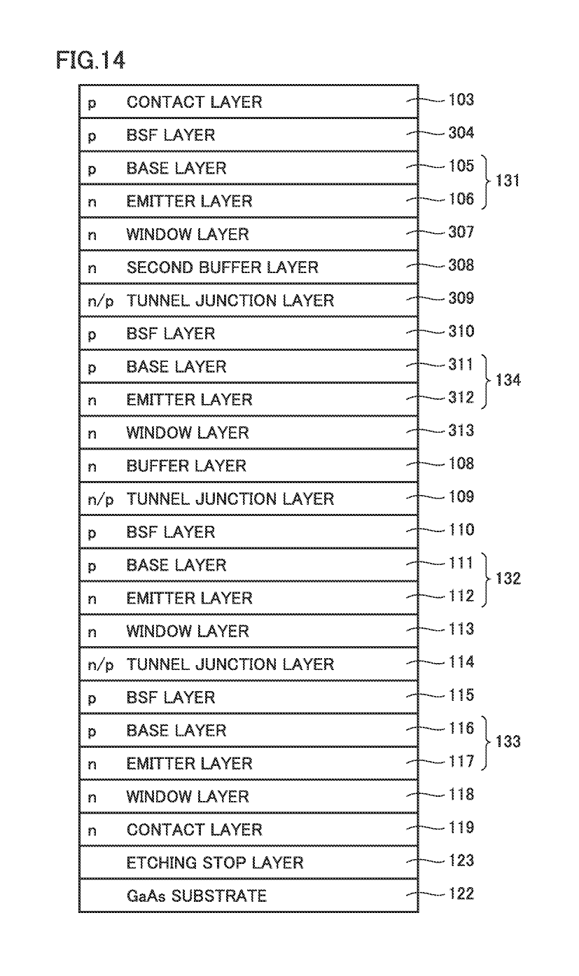

The following will describe an example of a method of manufacturing a Group III-V compound semiconductor solar cell in accordance with Embodiment 3 in reference to the schematic structural cross-sectional views in FIGS. 14 to 16.

First, referring to FIG. 14, a GaAs substrate 122 is placed in a MOCVD device. An etching stop layer 123, the n-type contact layer 119, the n-type window layer 118, the n-type emitter layer 117, the p-type base layer 116, and the p-type BSF layer 115 are then epitaxially grown in this sequence on the GaAs substrate 122 by MOCVD. The etching stop layer 123 and GaAs can be etched selectively.

Next, the tunnel junction layer 114 is formed on the p-type BSF layer 115 by MOCVD.

Next, the n-type window layer 113, the n-type emitter layer 112, the p-type base layer 111, and the p-type BSF layer 110 are epitaxially grown in this sequence on the tunnel junction layer 114 by MOCVD.

Next, the tunnel junction layer 109 is formed on the p-type BSF layer 110 by MOCVD.

Next, the n-type buffer layer 108 is epitaxially grown on the tunnel junction layer 109 by MOCVD. The n-type buffer layer 108 of the present embodiment is formed by the same method as the n-type buffer layer 108 of Embodiment 1.

Next, the n-type window layer 313, the n-type emitter layer 312, the p-type base layer 311, and the p-type BSF layer 310 are epitaxially grown in this sequence on the n-type buffer layer 108 by MOCVD.

Next, the tunnel junction layer 309 is formed on the p-type BSF layer 310 by MOCVD.

Next, the second n-type buffer layer 308 is epitaxially grown on the tunnel junction layer 309 by MOCVD. In the present embodiment, the second n-type buffer layer 308 is epitaxially grown in the following manner.

First, the flow rates of TMI, TMG and TMA, which are Group III element gases, are adjusted so as to grow n-type (Al_{0.6}Ga_{0.4})_{0.69}In_{0.31}As. After the flow rates are adjusted, this mixed growth gas starts to be introduced into a chamber. Throughout the introduction of the growth gas into the chamber, the ratio of the flow rate of TMI to the total flow rate of TMI, TMG, and TMA in the growth gas is continuously increased (in the present embodiment, linearly increased (monotonically increased)). These procedures grow the I sublayer in which the In composition ratio continuously changes (monotonically increases) from n-type (Al_{0.6}Ga_{0.4})_{0.69}In_{0.31}As to n-type (Al_{0.6}Ga_{0.4})_{0.64}In_{0.36}As.

Next, the growth gas stops being introduced into the chamber. Then, with no growth gas being introduced into the chamber, the flow rates are adjusted so as to further increase the ratio of the flow rate of TMI to the total flow rate of TMI, TMG, and TMA.

After the flow rates are adjusted, this growth gas starts to be introduced into the chamber. Throughout the introduction of the growth gas into the chamber, the ratio of the flow rate of TMI to the total flow rate of TMI, TMG, and TMA in the growth gas is continuously increased (monotonically increased). These procedures grow, on the I sublayer, the H sublayer in which the In composition ratio continuously changes (monotonically increases) from n-type (Al_{0.6}Ga_{0.4})_{0.59}In_{0.41}As to n-type (Al_{0.6}Ga_{0.4})_{0.54}In_{0.46}As.

Next, the growth gas stops being introduced into the chamber. Then, with no growth gas being introduced into the chamber, the flow rates are adjusted so as to further increase the ratio of the flow rate of TMI to the total flow rate of TMI, TMG, and TMA.

After the flow rates are adjusted, this growth gas starts to be introduced into the chamber. Throughout the introduction of the growth gas into the chamber, the ratio of the flow rate of TMI to the total flow rate of TMI, TMG, and TMA in the growth gas is continuously increased (monotonically increased). These procedures grow, on the H sublayer, the G sublayer in which the In composition ratio continuously changes (monotonically increases) from n-type (Al_{0.6}Ga_{0.4})_{0.48}In_{0.52}As to n-type (Al_{0.6}Ga_{0.4})_{0.43}In_{0.57}As.

Next, the growth gas stops being introduced into the chamber. Then, with no growth gas being introduced into the chamber, the flow rates are adjusted so as to further increase the ratio of the flow rate of TMI to the total flow rate of TMI, TMG, and TMA.

After the flow rates are adjusted, this growth gas starts to be introduced into the chamber. The growth gas is introduced into the chamber, this time without changing the ratio of the flow rate of TMI to the total flow rate of TMI, TMG, and TMA in the growth gas. These procedures grow, on the G sublayer, the F sublayer composed of n-type (Al_{0.6}Ga_{0.4})_{0.38}In_{0.62}As, which completes the epitaxial growth of the second n-type buffer layer 308 on the tunnel junction layer 309.

Next, the n-type window layer 307, the n-type emitter layer 106, the p-type base layer 105, the p-type BSF layer 304, and the p-type contact layer 103 are epitaxially grown in this sequence on the second n-type buffer layer 308 by MOCVD.

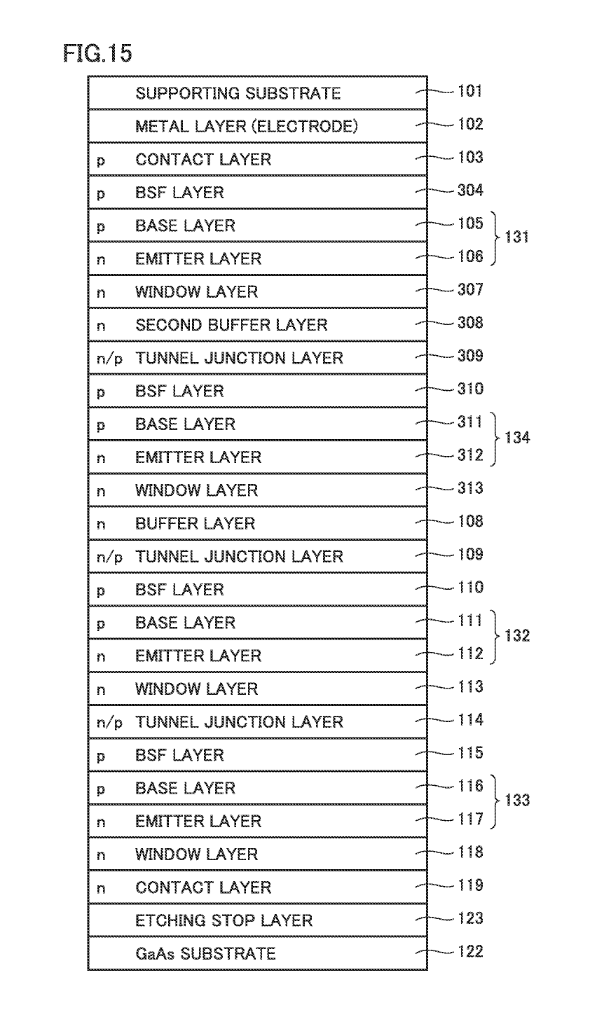

Next, as shown in FIG. 15, the supporting substrate 101 is attached via the metal layer 102 onto the contact layer 103 which is composed of p-type InGaAs.

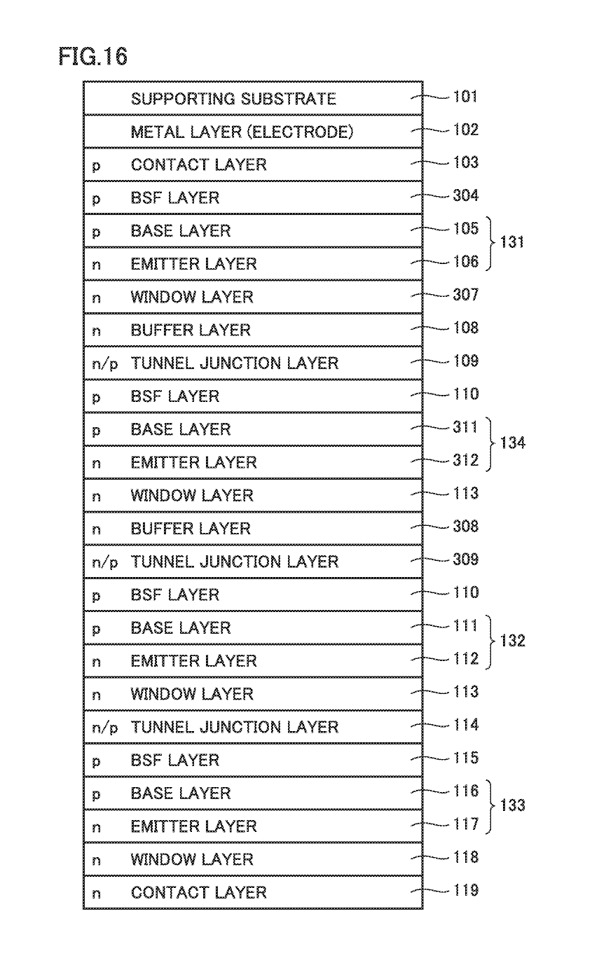

Next, as shown in FIG. 16, after etching the GaAs substrate 122 with an alkali aqueous solution, the etching stop layer 123 is etched with an acid aqueous solution.

Next, a resist pattern is formed on the n-type GaAs contact layer 119 by photolithography. After the resist pattern is formed, the contact layer 119 is partially removed by etching using an alkali aqueous solution. A resist pattern is then formed on the surface of the remaining contact layer 119 again by photolithography. Subsequently, the metal layer 121 is formed using a resistance heating vapor deposition device and an EB vapor deposition device.

Next, a mesa etching pattern is formed. After that, mesa etching is performed using an alkali aqueous solution and an acid solution. A laminate of, for example, a TiO₂ film and an Al₂O₃ film is then formed by electron beam (EB) vapor deposition, to provide the antireflective film 120. That concludes the manufacture of a Group III-V compound semiconductor solar cell in accordance with Embodiment 3 that has the structure shown in FIG. 13 in which the compound semiconductor solar cell has a light-receiving face on a side located opposite the direction of growth of the compound semiconductors.

Similarly to the n-type buffer layer 108, the second n-type buffer layer 308 of the Group III-V compound semiconductor solar cell in accordance with Embodiment 3 has a portion in which first segments and second segments are alternately provided. The “first segments” refer to the G sublayer, the H sublayer, and the I sublayer in each of which the In composition ratio monotonically increases with an increasing thickness of the second n-type buffer layer 308 as traced from a side located opposite where the bottom cell 131 is disposed toward the side where the bottom cell 131 is disposed. The “second segments” refer to the interface between the F sublayer and the G sublayer, the interface between the G sublayer and the H sublayer, and the interface between the H sublayer and the I layer. Across each of these interfaces, the In composition ratio monotonically increases without an increase in the thickness of the second n-type buffer layer 308.

Therefore, in the Group III-V compound semiconductor solar cell in accordance with Embodiment 3, the second n-type buffer layer 308, as well as the n-type buffer layer 108, has the same configuration and functions as the n-type buffer layer 108. The second n-type buffer layer 308 hence also contributes to reduction of the thickness of the buffer layer while restraining deterioration of properties.

In other respects, the same description as given in Embodiments 1 and 2 applies to Embodiment 3. The description is therefore not repeated here.

### Embodiment 4

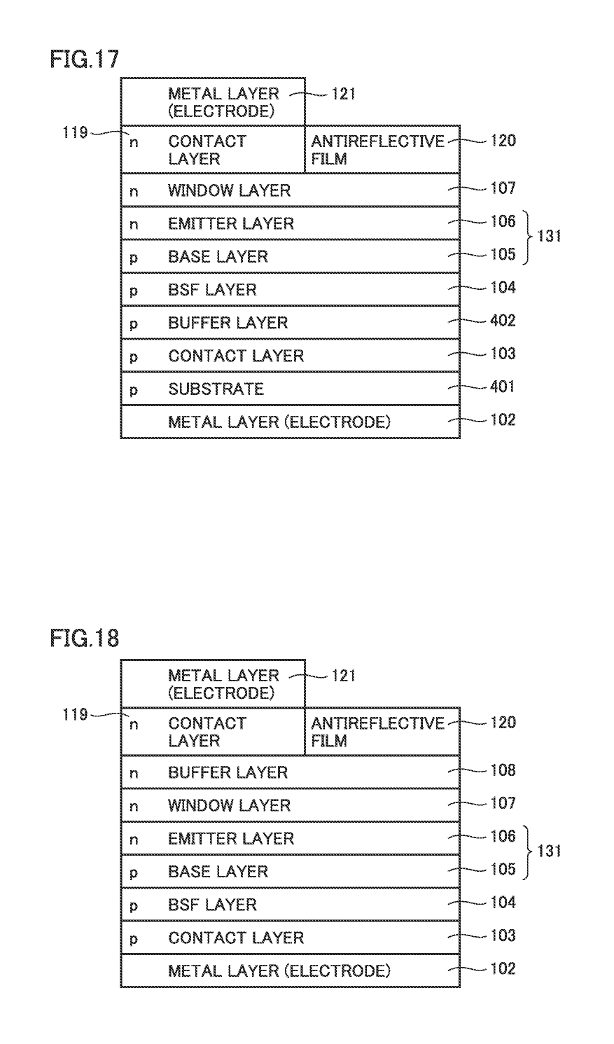

FIG. 17 is a schematic structural cross-sectional view of a Group III-V compound semiconductor solar cell in accordance with Embodiment 4. The Group III-V compound semiconductor solar cell in accordance with Embodiment 4 has a feature that it is a single-junction Group III-V compound semiconductor solar cell manufactured by forward stacking.

As shown in FIG. 17, the Group III-V compound semiconductor solar cell in accordance with Embodiment 4 has a structure in which a substrate 401, a p-type contact layer 103, a p-type buffer layer 402, a p-type BSF layer 104, a p-type base layer 105, an n-type emitter layer 106, and an n-type window layer 107 are stacked in this sequence on a metal layer 102 (electrode). The substrate 401 is composed of, for example, p-type GaAs. The p-type BSF layer 104 and the p-type base layer 105, the latter being composed of p-type InGaAs, have equal or similar lattice constants. In addition, an antireflective film 120 is provided on the n-type window layer 107, and a metal layer 121 (electrode) is provided on a contact layer 119 that is in turn provided on the n-type window layer 107. The p-type buffer layer 402 and the n-type buffer layer 108 have the same configuration, except for conductivity type.

The Group III-V compound semiconductor solar cell in accordance with Embodiment 4 is manufactured by: sequentially growing the p-type contact layer 103, the p-type buffer layer 402, the p-type BSF layer 104, the p-type base layer 105, the n-type emitter layer 106, the n-type window layer 107, and the n-type contact layer 119 on the substrate 401; partially removing the contact layer 119 to expose the n-type window layer 107; thereafter forming the metal layer 121 (electrode) on the contact layer 119; forming the antireflective film 120 on the exposed n-type window layer 107; and forming the metal layer (electrode) 102 on the substrate 401.

In the Group III-V compound semiconductor solar cell in accordance with Embodiment 4, the p-type buffer layer 402 has the same configuration and function as the n-type buffer layer 108. The p-type buffer layer 402 therefore contributes to reduction of the thickness of the buffer layer while restraining deterioration of properties.

In other respects, the same description as given in Embodiments 1 to 3 applies to Embodiment 4. The description is therefore not repeated here.

### Embodiment 5

FIG. 18 is a schematic structural cross-sectional view of a Group III-V compound semiconductor solar cell in accordance with Embodiment 5. The Group III-V compound semiconductor solar cell in accordance with Embodiment 5 has a feature that it is a single-junction Group III-V compound semiconductor solar cell manufactured by reverse stacking.

As shown in FIG. 18, the Group III-V compound semiconductor solar cell in accordance with Embodiment 5 has a structure in which a p-type contact layer 103, a p-type BSF layer 104, a p-type base layer 105, an n-type emitter layer 106, an n-type window layer 107, and an n-type buffer layer 108 are stacked in this sequence on a metal layer 102 (electrode). The p-type BSF layer 104 and the p-type base layer 105, the latter being composed of p-type InGaAs, have equal or similar lattice constants. In addition, an antireflective film 120 is provided on the n-type buffer layer 108, and a metal layer 121 (electrode) is provided on a contact layer 119 that is in turn provided on the n-type buffer layer 108.

The Group III-V compound semiconductor solar cell in accordance with Embodiment 5 is manufactured by: sequentially growing the n-type contact layer 119, the n-type buffer layer 108, the n-type window layer 107, the n-type emitter layer 106, the p-type base layer 105, the p-type BSF layer 104, and the p-type contact layer 103 on a substrate (not shown); partially removing the contact layer 119 to expose the window layer 107; thereafter forming the metal layer 121 (electrode) on the contact layer 119; forming the antireflective film 120 on the exposed window layer 107, which is composed of n-type InGaP; and forming the metal layer 102 (electrode) on the contact layer 103.

In other respects, the same description as given in Embodiments 1 to 4 applies to Embodiment 5. The description is therefore not repeated here.

### Embodiment 6

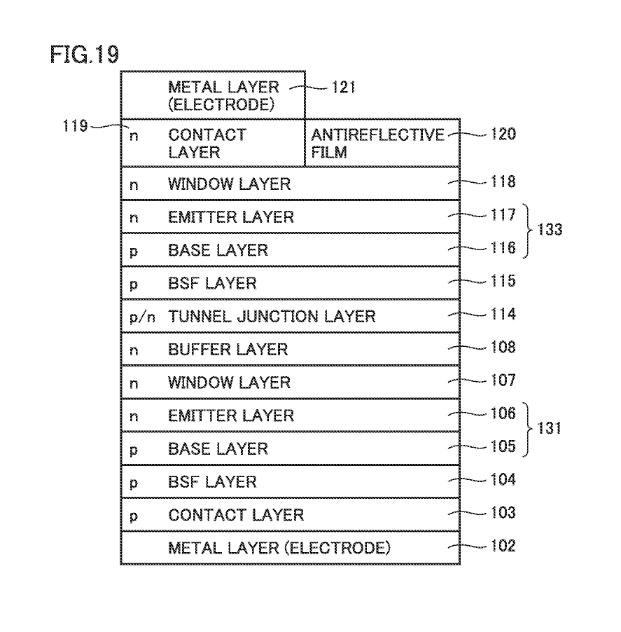

FIG. 19 is a schematic structural cross-sectional view of a Group III-V compound semiconductor solar cell in accordance with Embodiment 6. The Group III-V compound semiconductor solar cell in accordance with Embodiment 6 has a feature that it is a double-junction Group III-V compound semiconductor solar cell.

As shown in FIG. 19, the Group III-V compound semiconductor solar cell in accordance with Embodiment 6 has a structure in which a p-type contact layer 103, a p-type BSF layer 104, a p-type base layer 105, an n-type emitter layer 106, and an n-type window layer 107 are stacked in this sequence on a metal layer 102 (electrode). The p-type BSF layer 104 and the p-type base layer 105, the latter being composed of p-type InGaAs, have equal or similar lattice constants.

An n-type buffer layer 108 is stacked on the n-type window layer 107, and a tunnel junction layer 114 is stacked on the n-type buffer layer 108.

On the tunnel junction layer 114 are there stacked a p-type BSF layer 115, a p-type base layer 116, an n-type emitter layer 117 and an n-type window layer 118 in this sequence. The p-type BSF layer 115 and the p-type base layer 116, the latter being composed of p-type InGaP, have equal or similar lattice constants. The tunnel junction layer 114 includes an n-type layer and a p-type layer that have a lattice constant equal or similar to that of the p-type base layer 116.

An antireflective film 120 is provided on the n-type window layer 118, and a metal layer 121 (electrode) is provided on a contact layer 119 that is in turn provided on the n-type window layer 118.

The Group III-V compound semiconductor solar cell in accordance with Embodiment 6 is manufactured by: sequentially growing the n-type contact layer 119, the n-type window layer 118, the n-type emitter layer 117, the p-type base layer 116, the p-type BSF layer 115, the tunnel junction layer 114, the n-type buffer layer 108, the n-type window layer 107, the n-type emitter layer 106, the p-type base layer 105, the p-type BSF layer 104, and the p-type contact layer 103 on a substrate (not shown); partially removing the contact layer 119 to expose the window layer 118; thereafter forming the metal layer 121 (electrode) on the contact layer 119; forming the antireflective film 120 on the exposed window layer 118, which is composed of n-type AlInP; and forming the metal layer 102 (electrode) on the contact layer 103.

In other respects, the same description as given in Embodiments 1 to 5 applies to Embodiment 6. The description is therefore not repeated here.

### Embodiment 7

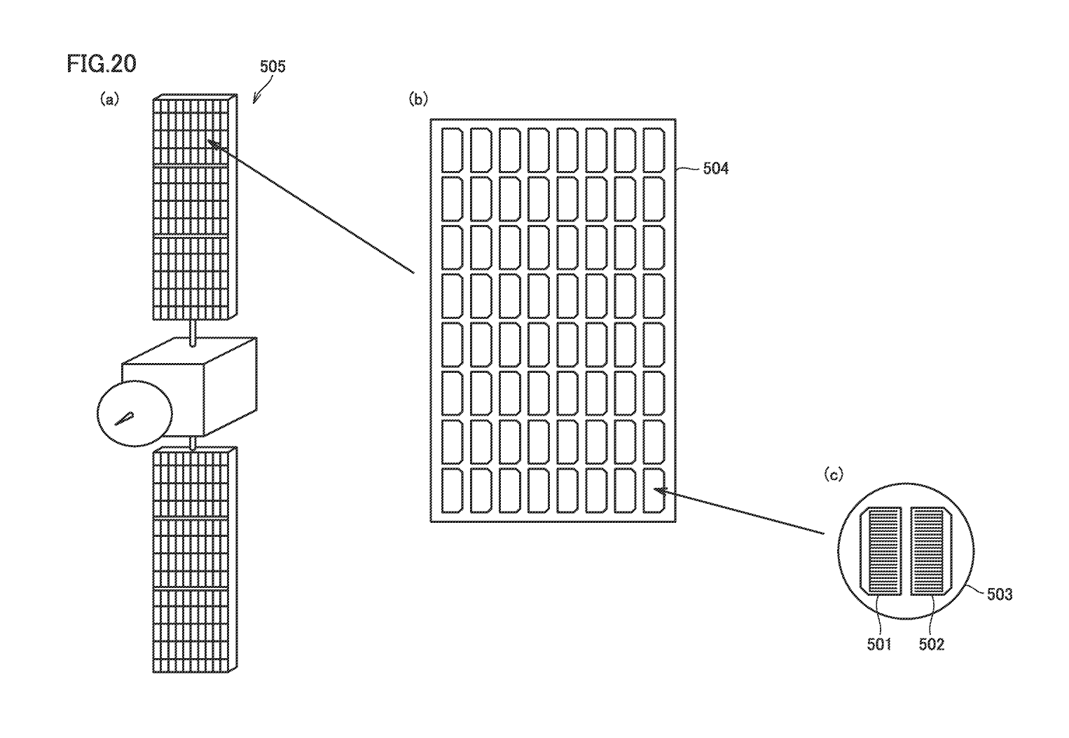

FIG. 20(a) is a schematic perspective view of an artificial satellite in accordance with Embodiment 7; FIG. 20(b) is a schematic plan view of a solar cell array in accordance with Embodiment 7 used in the artificial satellite in accordance with Embodiment 7; and FIG. 20(c) is a schematic plan view of Group III-V compound semiconductor solar cells in accordance with Embodiments 1 to 6 used in the solar cell array in accordance with Embodiment 7.

In an artificial satellite 505 in accordance with Embodiment 7 shown in FIG. 20(a), for example, two Group III-V compound semiconductor solar cells 501 and 502 are formed on a 4-inch substrate 503 by any of the methods described in Embodiments 1 to 6. The Group III-V compound semiconductor solar cells 501 and 502 formed on the substrate 503 in accordance with one of Embodiments 1 to 6 are then separated, for example, by dicing or laser light. Thereafter, the Group III-V compound semiconductor solar cells are fitted with respective bypass diodes so that a degraded property of a Group III-V compound semiconductor solar cell does not lead to a degraded property of an entire solar cell array 504.

A p-electrode and an n-electrode of these adjacent Group III-V compound semiconductor solar cells are connected using an interconnector. The connected Group III-V compound semiconductor solar cells are attached to a board called a “paddle” using an adhesion material as shown in FIG. 20(b), to form the solar cell array 504. The finished solar cell array 504 is mounted to an artificial satellite as a power supply source, to fabricate the artificial satellite 505 in accordance with Embodiment 7 shown in FIG. 20(a).

In other respects, the same description as given in Embodiments 1 to 6 applies to Embodiment 7. The description is therefore not repeated here.

The following will describe the Group III-V compound semiconductor solar cells in accordance with the embodiments in more detail by means of a working example. The present invention is however by no means limited to the configurations presented in the working example.

### Working Example

Group III-V compound Semiconductor Solar Cell in Accordance with Working Example A Group III-V compound semiconductor solar cell that had a structure shown in FIG. 17 was prepared as a Group III-V compound semiconductor solar cell in accordance with the working example. This Group III-V compound semiconductor solar cell in accordance with the working example was fabricated in the following manner. First, a p-type contact layer 103, a p-type buffer layer 402, a p-type BSF layer 104, a p-type base layer 105, an n-type emitter layer 106, an n-type window layer 107, and an n-type contact layer 119 were sequentially grown on a p-type GaAs substrate 401. The p-type BSF layer 104 and the p-type base layer 105, the latter being composed of p-type InGaAs, had equal or similar lattice constants. Next, the contact layer 119 was partially removed to expose the n-type window layer 107. After that, a metal layer 121 (electrode) was formed on the contact layer 119. An antireflective film 120 was then formed on the exposed n-type window layer 107. Next, a metal layer 102 (electrode) was formed on the p-type contact layer 103, which completed the fabrication of the Group III-V compound semiconductor solar cell in accordance with the working example.

In the Group III-V compound semiconductor solar cell in accordance with the working example, the p-type buffer layer 402 was formed in the following manner. First, the flow rates of TMI and TMG were adjusted so as to grow p-type In_{0.48}Ga_{0.52}P. After the flow rates were adjusted, this growth gas started to be introduced into the chamber. Throughout the introduction of the growth gas into the chamber, the ratio of the flow rate of TMI to the total flow rate of TMI and TMG in the growth gas was continuously increased (monotonically increased). These procedures grew a D sublayer in which the In composition ratio continuously changed (monotonically increased) from p-type In_{0.48}Ga_{0.52}P to p-type In_{0.52}Ga_{0.48}P.

Next, the growth gas stopped being introduced into the chamber. Then, with no growth gas being introduced into the chamber, the flow rates were adjusted so as to further increase the ratio of the flow rate of TMI to the total flow rate of TMI and TMG.

After the flow rates were adjusted, this growth gas started to be introduced into the chamber. Throughout the introduction of the growth gas into the chamber, the ratio of the flow rate of TMI to the total flow rate of TMI and TMG in the growth gas was continuously increased (monotonically increased). These procedures grew, on the D sublayer, a C sublayer in which the In composition ratio continuously changed (monotonically increased) from p-type In_{0.56}Ga_{0.44}P to p-type In_{0.61}Ga_{0.39}P.

Next, the growth gas stopped being introduced into the chamber. Then, with no growth gas being introduced into the chamber, the flow rates were adjusted so as to further increase the ratio of the flow rate of TMI to the total flow rate of TMI and TMG.

After the flow rates were adjusted, this growth gas started to be introduced into the chamber. Throughout the introduction of the growth gas into the chamber, the ratio of the flow rate of TMI to the total flow rate of TMI and TMG in the growth gas was continuously increased (monotonically increased). These procedures grew, on the C sublayer, a B sublayer in which the In composition ratio continuously changed (monotonically increased) from p-type In_{0.65}Ga_{0.35}P to p-type In_{0.69}Ga_{0.31}P.

Next, the growth gas stopped being introduced into the chamber. Then, with no growth gas being introduced into the chamber, the flow rates were adjusted so as to further increase the ratio of the flow rate of TMI to the total flow rate of TMI and TMG.

After the flow rates were adjusted, this growth gas started to be introduced into the chamber. Throughout the introduction of the growth gas into the chamber, the ratio of the flow rate of TMI to the total flow rate of TMI and TMG in the growth gas was continuously increased (monotonically increased). These procedures grew, on the B sublayer, an A sublayer in which the In composition ratio continuously changed (monotonically increased) from p-type In_{0.73}Ga_{0.27}P to p-type In_{0.78}Ga_{0.22}P.

Next, the growth gas stopped being introduced into the chamber. Then, with no growth gas being introduced into the chamber, the flow rates were adjusted so as to further increase the ratio of the flow rate of TMI to the total flow rate of TMI and TMG.

After the flow rates were adjusted, this growth gas started to be introduced into the chamber. The growth gas was introduced into the chamber, this time without changing the ratio of the flow rate of TMI to the total flow rate of TMI and TMG in the growth gas. These procedures grew, on the A sublayer, an E sublayer composed of p-type In_{0.82}Ga_{0.18}P, which completed the epitaxial growth of the p-type buffer layer 402 on the contact layer 103 composed of p-type InGaAs.

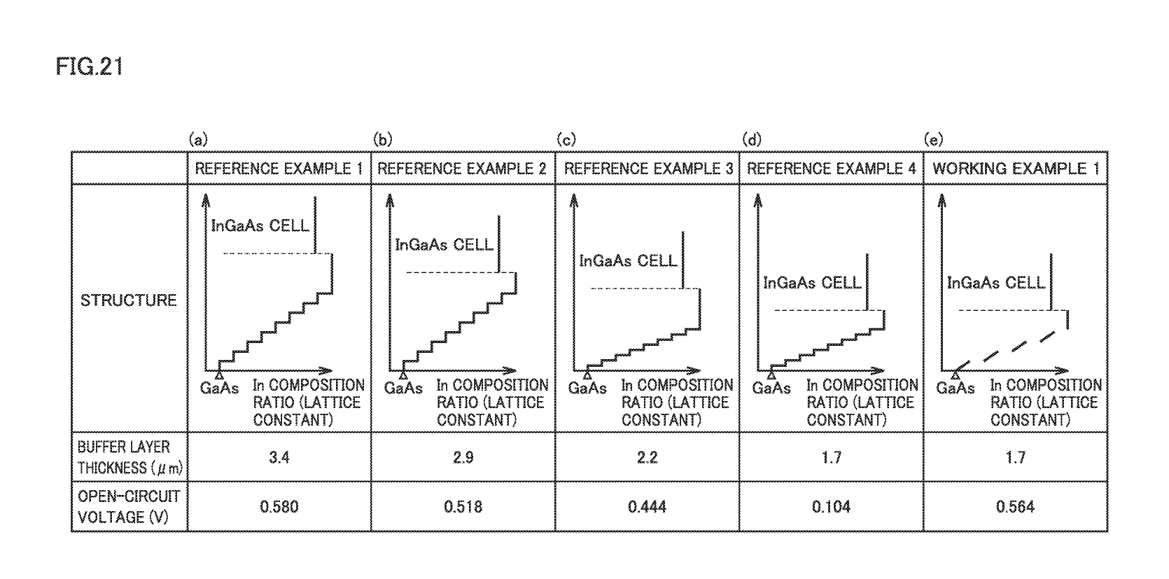

The thickness and V_{oc} of the p-type buffer layer 402 in the Group III-V compound semiconductor solar cell fabricated as above in accordance with the working example were evaluated. Results are shown in FIG. 21(e). As shown in FIG. 21(e), the p-type buffer layer 402 in the Group III-V compound semiconductor solar cell in accordance with the working example had a thickness of 1.7 μm and a V_{oc} of 0.564 V. The V_{oc} of the Group III-V compound semiconductor solar cell in accordance with the working example was obtained from measurement of current-voltage characteristics under artificial sunlight (air mass=1.5) shone at an energy density of 1 kW/m² by a solar simulator.

### Group III-V Compound Semiconductor Solar Cells in Accordance with Reference Examples 1 to 4

Group III-V compound semiconductor solar cells in accordance with Reference Examples 1 to 4 were fabricated in the same manner as the Group III-V compound semiconductor solar cell in accordance with the working example, except that the p-type buffer layer 402 was replaced by a step-graded buffer layer formed under different conditions. The thickness and V_{oc} of the buffer layer in each of the Group III-V compound semiconductor solar cells in accordance with Reference Examples 1 to 4 were evaluated. Results are shown in FIGS. 21(a) to 21(d).

As shown in FIGS. 21(a) to 21(d), the buffer layers in the Group III-V compound semiconductor solar cells in accordance with Reference Examples 1 to 4 had respective thicknesses of 3.4 μm (Reference Example 1), 2.9 μm (Reference Example 2), 2.2 μm (Reference Example 3), and 1.7 μm (Reference Example 4).

As shown in FIGS. 21(a) to 21(d), the Group III-V compound semiconductor solar cells in accordance with Reference Examples 1 to 4 had respective V_{oc} of 0.580 V (Reference Example 1), 0.518 V (Reference Example 2), 0.444 V (Reference Example 3), and 0.104 V (Reference Example 4).

These results confirm that the Group III-V compound semiconductor solar cell in accordance with the working example allows for reduction of the thickness of the buffer layer while restraining V_{oc} from decreasing.

### Additional Remarks

An embodiment disclosed here is directed to a Group III-V compound semiconductor solar cell including: a first electrode; a second electrode; and a buffer layer and a first cell both between the first and second electrodes, wherein the buffer layer and the first cell contain a Group III-V compound semiconductor, and the buffer layer has a portion in which first segments and second segments are alternately provided, each of the first segments having a Group III element composition that continuously changes with an increasing thickness of the buffer layer as traced from a side located opposite where the first cell is disposed toward a side where the first cell is disposed, each of the second segments having a Group III element composition that changes without an increase in the thickness of the buffer layer.

In the Group III-V compound semiconductor solar cell in accordance with the embodiment disclosed here, the buffer layer may include a first sublayer and a second sublayer on the first sublayer, the first sublayer and the second sublayer may correspond to the first segments, and the first sublayer and the second sublayer may have therebetween an interface that corresponds to one of the second segments.

In the Group III-V compound semiconductor solar cell in accordance with the embodiment disclosed here, one of sublayers of the buffer layer that is located closest to the first cell preferably exhibits a smaller rate of change in Group III element composition than do the other sublayers of the buffer layer.

In the Group III-V compound semiconductor solar cell in accordance with the embodiment disclosed here, the Group III element composition preferably changes by an amount of less than or equal to 0.08 in each of the first segments.

In the Group III-V compound semiconductor solar cell in accordance with the embodiment disclosed here, a total sum of amounts of change in Group III element composition that occur in the first segments is preferably more than or equal to ⅓ a total sum of amounts of change in Group III element composition that occur across the second segments.

In the Group III-V compound semiconductor solar cell in accordance with the embodiment disclosed here, each of the first segments may have a lattice constant that continuously increases with an increasing thickness of the buffer layer as traced from the side located opposite where the first cell is disposed toward the side where the first cell is disposed, and each of the second segments may have a lattice constant that increases without an increase in the thickness of the buffer layer.

In the Group III-V compound semiconductor solar cell in accordance with the embodiment disclosed here, one of the first segments of the buffer layer that is located closest to the first cell preferably exhibits a smaller rate of change in lattice constant than do the other first segments of the buffer layer.

In the Group III-V compound semiconductor solar cell in accordance with the embodiment disclosed here, the lattice constant preferably changes at a rate of from 0.1% to 1% inclusive in each of the first segments.

In the Group III-V compound semiconductor solar cell in accordance with the embodiment disclosed here, the lattice constant more preferably changes at a rate of from 0.2% to 0.4% inclusive in each of the first segments.

In the Group III-V compound semiconductor solar cell in accordance with the embodiment disclosed here, a total sum of amounts of change in lattice constant that occur in the first segments of the buffer layer is preferably more than or equal to ⅓ a total sum of amounts of change in lattice constant that occur across the second segments of the buffer layer.

In the Group III-V compound semiconductor solar cell in accordance with the embodiment disclosed here, the buffer layer may contain InₓGa_{y}P (0≤x≤1, 0≤y≤1, (x+y)>0).

The Group III-V compound semiconductor solar cell in accordance with the embodiment disclosed here may further include a second cell opposite and across the buffer layer from the first cell between the first and second electrodes, wherein the second cell contains a Group III-V compound semiconductor.

The Group III-V compound semiconductor solar cell in accordance with the embodiment disclosed here may further include a third cell opposite and across the second cell from the buffer layer between the first and second electrodes, wherein the third cell contains a Group III-V compound semiconductor.

The Group III-V compound semiconductor solar cell in accordance with the embodiment disclosed here may further include a fourth cell opposite and across the third cell from the buffer layer between the first and second electrodes, wherein the fourth cell contains a Group III-V compound semiconductor.

Another embodiment disclosed here is directed to a method of manufacturing a Group III-V compound semiconductor solar cell, the method including the steps of: forming a buffer layer on a substrate; and forming a first cell on the buffer layer, wherein the buffer layer is formed to have a portion in which first segments and second segments are alternately provided, each of the first segments having a Group III element composition that continuously changes with an increasing thickness of the buffer layer as traced from a side located opposite where the first cell is disposed toward a side where the first cell is disposed, each of the second segments having a Group III element composition that changes without an increase in the thickness of the buffer layer.

In the method of manufacturing a Group III-V compound semiconductor solar cell in accordance with the embodiment disclosed here, the buffer layer forming step may include the alternately repeated steps of: continuously changing a Group III element gas composition while introducing a growth gas; and changing the Group III element gas composition while introducing no growth gas.

In the method of manufacturing a Group III-V compound semiconductor solar cell in accordance with the embodiment disclosed here, the buffer layer is preferably formed such that one of sublayers of the buffer layer that is located closest to the first cell exhibits a smaller rate of change in Group III element composition than do the other sublayers of the buffer layer.

In the method of manufacturing a Group III-V compound semiconductor solar cell in accordance with the embodiment disclosed here, the buffer layer is preferably formed such that the Group III element composition changes by an amount of less than or equal to 0.08 in each of the first segments.

In the method of manufacturing a Group III-V compound semiconductor solar cell in accordance with the embodiment disclosed here, the buffer layer is preferably formed such that a total sum of amounts of change in Group III element composition that occur in the first segments is more than or equal to ⅓ a total sum of amounts of change in Group III element composition that occur across the second segments.

In the method of manufacturing a Group III-V compound semiconductor solar cell in accordance with the embodiment disclosed here, the buffer layer may be formed such that each of the first segments has a lattice constant that continuously increases with an increasing thickness of the buffer layer as traced from the side located opposite where the first cell is disposed toward the side where the first cell is disposed, and each of the second segments has a lattice constant that increases without an increase in the thickness of the buffer layer.

In the method of manufacturing a Group III-V compound semiconductor solar cell in accordance with the embodiment disclosed here, the buffer layer is preferably formed such that one of the first segments of the buffer layer that is located closest to the first cell exhibits a smaller rate of change in lattice constant than do the other first segments of the buffer layer.

In the method of manufacturing a Group III-V compound semiconductor solar cell in accordance with the embodiment disclosed here, the buffer layer is preferably formed such that the lattice constant changes at a rate of from 0.1% to 1% inclusive in each of the first segments.

In the method of manufacturing a Group III-V compound semiconductor solar cell in accordance with the embodiment disclosed here, the buffer layer is preferably formed such that the lattice constant changes at a rate of from 0.2% to 0.4% inclusive in each of the first segments.

In the method of manufacturing a Group III-V compound semiconductor solar cell in accordance with the embodiment disclosed here, the buffer layer is preferably formed such that a total sum of amounts of change in lattice constant that occur in the first segments of the buffer layer is more than or equal to ⅓ a total sum of amounts of change in lattice constant that occur across the second segments of the buffer layer.

In the method of manufacturing a Group III-V compound semiconductor solar cell in accordance with the embodiment disclosed here, the buffer layer may be formed to contain InₓGa_{y}P (0≤x≤1, 0≤y≤1, (x+y)>0).

The method of manufacturing a Group III-V compound semiconductor solar cell in accordance with the embodiment disclosed here may further include the step of forming a second cell on the first cell, the second cell containing a Group III-V compound semiconductor.

The method of manufacturing a Group III-V compound semiconductor solar cell in accordance with the embodiment disclosed here may further include the step of forming a third cell on the second cell, the third cell containing a Group III-V compound semiconductor.

The method of manufacturing a Group III-V compound semiconductor solar cell in accordance with the embodiment disclosed here may further include the step of forming a fourth cell on the third cell, the fourth cell containing a Group III-V compound semiconductor.

A further embodiment disclosed here is directed to an array of electrically connected Group III-V compound semiconductor solar cells described above.

Still another embodiment disclosed here is directed to an artificial satellite including the array of solar cells.

It is envisaged that the embodiments and examples described in the foregoing may be combined where appropriate.

The embodiments and examples disclosed here are for illustrative purposes only in every respect and provide no basis for restrictive interpretations. The scope of the present invention is defined only by the claims and never bound by the specification. Those modifications and variations that may lead to equivalents of claimed elements are all included within the scope of the invention.

### INDUSTRIAL APPLICABILITY

The embodiments disclosed here may be applied to Group III-V compound semiconductor solar cells, methods of manufacturing Group III-V compound semiconductor solar cells, solar cell arrays, and artificial satellites.

### REFERENCE SIGNS LIST

101 Supporting Substrate
102 Metal Layer
103 Contact Layer
104 BSF Layer
105 Base Layer
106 Emitter Layer
107 Window Layer
108 N-type Buffer Layer
109 Tunnel Junction Layer
110 BSF Layer
111 Base Layer
112 Emitter Layer
113 Window Layer
114 Tunnel Junction Layer
115 BSF Layer
116 Base Layer
117 Emitter Layer
118 Window Layer
119 Contact Layer
120 Antireflective Film
121 Metal Layer
122 GaAs Substrate
123 Etching Stop Layer
131 Bottom Cell
132 Middle Cell
133 Top Cell
141a D Sublayer
141b A Interface
142a C Sublayer
142b B Interface
143a B Sublayer
143b C Interface
144a A Sublayer
144b D Interface
145a F Sublayer
201 Ge Substrate
304 BSF Layer
307 Window Layer
308 Second N-type Buffer Layer
309 Tunnel Junction Layer
310 BSF Layer
311 Base Layer
312 Emitter Layer
313 Window Layer
501, 502 Group III-V Compound Semiconductor Solar Cell
503 Substrate
504 Solar Cell Array
505 Artificial Satellite

1. A Group III-V compound semiconductor solar cell comprising:
a first electrode;
a second electrode; and
a buffer layer and a first cell both between the first and second electrodes,
wherein
the buffer layer and the first cell contain a Group III-V compound semiconductor, and
the buffer layer has a portion in which first segments and second segments are alternately provided, each of the first segments having a Group III element composition that continuously changes with an increasing thickness of the buffer layer as traced from a side located opposite where the first cell is disposed toward a side where the first cell is disposed, each of the second segments having a Group III element composition that changes without an increase in the thickness of the buffer layer.

2. The Group III-V compound semiconductor solar cell according to claim 1, wherein:
the buffer layer includes a first sublayer and a second sublayer on the first sublayer;
the first sublayer and the second sublayer correspond to the first segments; and
the first sublayer and the second sublayer have therebetween an interface that corresponds to one of the second segments.

3. The Group III-V compound semiconductor solar cell according to claim 2, wherein one of sublayers of the buffer layer that is located closest to the first cell exhibits a smaller rate of change in Group III element composition than do the other sublayers of the buffer layer.

4. The Group III-V compound semiconductor solar cell according to claim 1, wherein a total sum of amounts of change in Group III element composition that occur in the first segments is more than or equal to ⅓ a total sum of amounts of change in Group III element composition that occur across the second segments.

5. The Group III-V compound semiconductor solar cell according to claim 1, further comprising a second cell opposite and across the buffer layer from the first cell between the first and second electrodes, wherein the second cell contains a Group III-V compound semiconductor.

6. The Group III-V compound semiconductor solar cell according to claim 5, further comprising a third cell opposite and across the second cell from the buffer layer between the first and second electrodes, wherein the third cell contains a Group III-V compound semiconductor.

7. A method of manufacturing a Group III-V compound semiconductor solar cell, the method comprising:
forming a buffer layer on a substrate; and
forming a first cell on the buffer layer,
wherein the buffer layer is formed to have a portion in which first segments and second segments are alternately provided, each of the first segments having a Group III element composition that continuously changes with an increasing thickness of the buffer layer as traced from a side located opposite where the first cell is disposed toward a side where the first cell is disposed, each of the second segments having a Group III element composition that changes without an increase in the thickness of the buffer layer.

8. An artificial satellite comprising an array of electrically connected Group III-V compound semiconductor solar cells described in claim 1.

9. The Group III-V compound semiconductor solar cell according to claim 2, wherein a total sum of amounts of change in Group III element composition that occur in the first segments is more than or equal to ⅓ a total sum of amounts of change in Group III element composition that occur across the second segments.

10. The Group III-V compound semiconductor solar cell according to claim 3, wherein a total sum of amounts of change in Group III element composition that occur in the first segments is more than or equal to ⅓ a total sum of amounts of change in Group III element composition that occur across the second segments.

11. The Group III-V compound semiconductor solar cell according to claim 10, further comprising a second cell opposite and across the buffer layer from the first cell between the first and second electrodes, wherein the second cell contains a Group compound semiconductor.

12. The Group III-V compound semiconductor solar cell according to claim 11, further comprising a third cell opposite and across the second cell from the buffer layer between the first and second electrodes, wherein the third cell contains a Group III-V compound semiconductor.

13. The Group III-V compound semiconductor solar cell according to claim 2, further comprising a second cell opposite and across the buffer layer from the first cell between the first and second electrodes, wherein the second cell contains a Group III-V compound semiconductor.

14. The Group III-V compound semiconductor solar cell according to claim 13, further comprising a third cell opposite and across the second cell from the buffer layer between the first and second electrodes, wherein the third cell contains a Group III-V compound semiconductor.

15. The Group III-V compound semiconductor solar cell according to claim 3, further comprising a second cell opposite and across the buffer layer from the first cell between the first and second electrodes, wherein the second cell contains a Group III-V compound semiconductor.

16. The Group III-V compound semiconductor solar cell according to claim 15, further comprising a third cell opposite and across the second cell from the buffer layer between the first and second electrodes, wherein the third cell contains a Group III-V compound semiconductor.

17. The Group III-V compound semiconductor solar cell according to claim 4, further comprising a second cell opposite and across the buffer layer from the first cell between the first and second electrodes, wherein the second cell contains a Group III-V compound semiconductor.

18. The Group III-V compound semiconductor solar cell according to claim 17, further comprising a third cell opposite and across the second cell from the buffer layer between the first and second electrodes, wherein the third cell contains a Group III-V compound semiconductor.
